(19) United States
(12) Patent Application Publication
(10) Pub. No.: US 2024/0174918 A1
(43) Pub. Date: May 30, 2024

(54) SEMICONDUCTOR NANOPARTICLE, A PRODUCTION METHOD THEREOF, AND ELECTRONIC DEVICE INCLUDING THE SAME

(71) Applicant: SAMSUNG ELECTRONICS CO., LTD., Suwon-si (KR)

(72) Inventors: Hyundong HA, Suwon-si (KR); Yuho WON, Suwon-si (KR); Taehyung KIM, Suwon-si (KR); Nayoun WON, Suwon-si (KR); Hogeun CHANG, Suwon-si (KR)

(21) Appl. No.: 18/517,112

(22) Filed: Nov. 22, 2023

(30) Foreign Application Priority Data
Nov. 24, 2022 (KR) 10-2022-0159795

(51) Int. Cl. C09K 11/62; C09D 11/037; C09D 11/50; C09K 11/02; H01L 33/00; H01L 33/06

(52) U.S. Cl. CPC C09K 11/621; C09D 11/037; C09D 11/50; C09K 11/02; H01L 33/0025; H01L 33/06; B82Y 20/00

(57) ABSTRACT

A semiconductor nanoparticle, a method of manufacturing the semiconductor nanoparticle, a composite including the semiconductor nanoparticle, a color conversion panel, and a display panel. The semiconductor nanoparticle includes silver, indium, gallium, and sulfur, and is configured to emit blue light, and exhibits a quantum yield of greater than or equal to about 40% and a full width at half maximum of less than 70 nm.

### CROSS-REFERENCE TO RELATED APPLICATION

This application claims priority to Korean Patent Application No. 10-2022-0159795 filed in the Korean Intellectual Property Office on Nov. 24, 2022, and all the benefits accruing therefrom under 35 U.S.C. § 119, the entire content of which is herein incorporated by reference.

### BACKGROUND

### 1. Field

A semiconductor nanoparticle, a method of producing the same, a color conversion panel including the semiconductor nanoparticle, and an electronic device including the same are provided.

### 2. Description of the Related Art

A semiconductor nanoparticle may exhibit different aspects than a corresponding bulk material having substantially the same composition, for example, in terms of physical properties (e.g., a bandgap energy, a luminescent property, or the like) that are intrinsic in the bulk material. The semiconductor nanoparticle may be configured to emit light upon excitation by an energy source such as incident light or an applied voltage. Luminescent nanostructures may find applicability in a variety of devices (e.g., a display panel or an electronic device including the display panel). From an environmental perspective, it is desirable to develop a luminescent nanoparticle that does not include a harmful heavy metal such as cadmium and/or lead and still exhibit desirable luminescent properties for electronic devices.

### SUMMARY

An aspect relates to a semiconductor nanoparticle capable of emitting light of a desired wavelength and exhibiting an improved optical property.

An aspect relates to a method of producing the semiconductor nanoparticle.

An aspect relates to an electronic device (for example, an electroluminescent device or a photoluminescent device) including the semiconductor nanoparticle.

In an aspect, the semiconductor nanoparticle includes silver, indium, gallium, and sulfur, wherein the semiconductor nanoparticle is configured to emit blue light,
wherein the blue light has a peak emission wavelength of greater than or equal to about 400 nanometers (nm) and less than 490 nm, and
wherein the semiconductor nanoparticle is configured to have a quantum yield (e.g., an absolute quantum yield) of greater than or equal to about 40%, and
wherein the semiconductor nanoparticle is configured to exhibit a full width at half maximum of less than or equal to about 70 nm.

The peak emission wavelength of the blue light may be greater than or equal to about 410 nm and less than or equal to about 480 nm. The peak emission wavelength of the blue light may be greater than or equal to about 420 nm and less than or equal to about 475 nm.

The quantum yield of the semiconductor nanoparticle may be greater than or equal to about 45%. The quantum yield of the semiconductor nanoparticle may be greater than or equal to about 50%, greater than or equal to about 60%, or greater than or equal to about 70%. The quantum yield of the semiconductor nanoparticle may approach 100%.

The full width at half maximum (FWHM) of the semiconductor nanoparticle may be less than or equal to about 55 nm, less than or equal to about 50 nm, or less than or equal to about 45 nm. The full width at half maximum may be greater than or equal to about 5 nm, greater than or equal to about 10 nm, greater than or equal to about 15 nm, or greater than or equal to about 25 nm.

In a photoluminescence spectrum of the semiconductor nanoparticle, a trap emission value defined by Equation 1 may be less than about 0.3:

trap emission value=A2/A1 Equation 1
wherein, in Equation 1,
A1 is an intensity at a peak emission wavelength, and
A2 is a maximum intensity in a tail wavelength range of the peak emission wavelength+greater than or equal to about 60 nm.

In the semiconductor nanoparticle, a mole ratio of gallium to a sum of indium and gallium [Ga:(In+Ga)] may be greater than or equal to about 0.85:1 and less than or equal to about 0.995:1. The mole ratio of gallium to a sum of indium and gallium [Ga:(In+Ga)] may be greater than or equal to about 0.88:1 or greater than or equal to about 0.905:1, and less than or equal to about 0.98:1, or less than or equal to about 0.975:1.

In the semiconductor nanoparticle, a mole ratio of indium to sulfur [In:S] may be greater than or equal to about 0.01:1, and less than or equal to about 0.1:1, or less than or equal to about 0.08:1. The mole ratio of indium to sulfur (In:S) may be less than or equal to about 0.075:1.

In the semiconductor nanoparticle, a mole ratio of silver to sulfur [Ag:S] may be less than or equal to about 0.4:1, less than or equal to about 0.35:1, less than or equal to about 0.345:1, less than or equal to about 0.34:1, less than or equal to about 0.32:1, or less than or equal to about 0.29:1, and greater than or equal to about 0.1:1. The mole ratio of silver to sulfur [Ag:S] may be less than or equal to about 0.26:1.

In the semiconductor nanoparticle, a mole ratio of gallium to sulfur (Ga:S) may be greater than or equal to about 0.55:1, greater than or equal to about 0.6:1, or greater than or equal to about 0.77:1, and less than or equal to about 2.5:1, less than or equal to about 2:1, or less than or equal to about 1.2:1.

In the semiconductor nanoparticle, a mole ratio of a sum of indium and gallium to sulfur [(In+Ga):S] may be greater than or equal to about 0.55:1, greater than or equal to about 0.6:1, or greater than or equal to about 0.65:1, and less than or equal to about 2.5:1, less than or equal to about 1.5:1, or less than or equal to about 1.3:1.

In the semiconductor nanoparticle, a mole ratio of a sum of indium and gallium to silver [(In+Ga):Ag] may be greater than or equal to about 1.9:1, or greater than or equal to about 2.1:1, and less than or equal to about 10:1, less than or equal to about 7:1, less than or equal to about 6.3:1, less than or equal to about 3.5:1, or less than or equal to about 3:1.

In the semiconductor nanoparticle, a mole ratio of silver to a sum of silver, indium, and gallium [Ag:(Ag+In+Ga)] may be less than about 0.38:1 and greater than or equal to about 0.09:1.

In the semiconductor nanoparticle, the mole ratio of sulfur to a sum of silver, indium, and gallium [S:(Ag+In+Ga)] may be greater than or equal to about 0.5:1, greater than or equal to about 0.65:1, or greater than or equal to about 0.7:1, and less than or equal to about 1.35:1.

In an embodiment, the semiconductor nanoparticle may not include lithium. In an embodiment, the semiconductor nanoparticle may not include sodium. In an embodiment, the semiconductor nanoparticle may not include an alkali metal.

An indium amount (or concentration) in a portion adjacent to a surface of the semiconductor nanoparticle may be less than an indium amount (or concentration) in a central portion (inner portion) thereof. The semiconductor nanoparticle or the shell may further include an inorganic layer including a zinc chalcogenide proximate to a surface thereof (for example, an outermost layer of the nanoparticle).

In an embodiment, the semiconductor nanoparticle may include a first semiconductor nanocrystal, a second semiconductor nanocrystal, or a combination thereof. In the semiconductor nanoparticle, the second semiconductor nanocrystal may be disposed on the first semiconductor nanocrystal or may surround at least a portion of the first semiconductor nanocrystal. In the semiconductor nanoparticle, the second semiconductor nanocrystal may be disposed between the first semiconductor nanocrystal and the inorganic layer. The first semiconductor nanocrystal may include silver, indium, gallium, and sulfur. The second semiconductor nanocrystal may include gallium, sulfur, and, optionally, silver.

A size or an average size (hereinafter, can be referred to as “size”) of the semiconductor nanoparticle may be greater than or equal to about 5 nm, greater than or equal to about 6 nm, or greater than or equal to about 6.1 nm. The size of the semiconductor nanoparticle may be less than or equal to about 20 nm, or less than or equal to about 15 nm. For example, the semiconductor nanoparticle may have a size greater than or equal to about 5 nm and less than or equal to about 20 nm, or greater than or equal to about 6 nm and less than or equal to about 15 nm.

In an embodiment, a method of producing the semiconductor nanoparticle may include heating a first reaction solution containing a first metal precursor and a first sulfur precursor to a first reaction temperature for a first reaction time to obtain a semiconductor nanocrystal; and reacting a second metal precursor and a second sulfur precursor in an organic solvent in the presence of the semiconductor nanocrystal to obtain the semiconductor nanoparticle, wherein the first metal precursor includes a first silver compound, a first gallium compound, and a first indium compound, and the second metal precursor includes a second gallium compound and, optionally, a second silver compound. In the first reaction solution, a mole ratio of gallium to indium for example as determined from the first gallium compound and the first indium compound is greater than or equal to about 3.5:1, and the first reaction temperature is greater than or equal to about 240° C.

The first reaction temperature can be greater than or equal to about 250° C., or greater than or equal to about 255° C., and less than or equal to about 300° ° C.

The reacting of the second metal precursor with the second sulfur precursor may include preparing a reaction medium containing the second sulfur precursor and the organic ligand in the organic solvent; heating the reaction medium to an addition temperature; adding the semiconductor nanocrystal and the second metal precursor to the reaction medium to obtain a reaction mixture; heating the reaction mixture to a second reaction temperature for a second reaction time, wherein the addition temperature above may be greater than or equal to about 120° C. and less than or equal to about 280° C., the second reaction temperature may be greater than or equal to about 180° C. and less than or equal to about 380° C.

The first reaction time can be greater than or equal to about 10 minutes and less than or equal to about 200 minutes. The first gallium compound may include a gallium acetylacetonate, and the second gallium compound may include a gallium halide. The first silver compound may contain a silver acetate. The first indium compound may include an indium halide. The first indium compound may include an indium halide, and the second gallium compound may include a gallium halide.

An embodiment relates to an ink composition including a liquid vehicle and the semiconductor nanoparticle. The semiconductor nanoparticle may be dispersed in the liquid vehicle. The liquid vehicle may include a liquid monomer, an organic solvent, or a combination thereof. The ink composition may further include a metal oxide nanoparticle.

An embodiment is directed to an electroluminescent device including the semiconductor nanoparticle described herein.

In an embodiment, the electroluminescent device includes a first electrode and a second electrode spaced apart from each other; and
a light emitting layer between the first electrode and the second electrode;
wherein the light emitting layer includes the semiconductor nanoparticle described herein.

The electroluminescent device may further include a hole auxiliary layer between the light emitting layer and the first electrode.

The electroluminescent device may further include an electron auxiliary layer between the light emitting layer and the second electrode.

The electroluminescent device may further include a hole auxiliary layer between the light emitting layer and the first electrode, and further include an electron auxiliary layer between the light emitting layer and the second electrode.

In an embodiment, the hole auxiliary layer may include a hole transport layer including an organic polymer compound.

In an embodiment, the hole auxiliary layer and the electron auxiliary layer may include a zinc magnesium metal oxide nanoparticle.

In an embodiment, a photoluminescent device includes a light source (e.g., a light emitting panel) and a color conversion element (e.g., a color conversion panel), wherein the light source is configured to provide incident light to the color conversion element and the color conversion element includes the semiconductor nanoparticle.

The color conversion element may include a semiconductor nanoparticle composite. The composite may include a matrix (e.g., a polymer matrix) and the semiconductor nanoparticle dispersed within the matrix.

The semiconductor nanoparticle composite may be in the form of a sheet. The semiconductor nanoparticle composite may be in the form of a patterned film.

The incident light may include blue light and, optionally, green light (e.g., the green light mixed in with the blue light). The blue light may have a peak emission wavelength of from about 440 nm to about 460 nm or from about 450 nm to about 455 nm. The light source (e.g., a light emitting panel) may include an organic light emitting diode, a micro LED, a mini LED, an LED including a nanorod, or a combination thereof.

In an embodiment, a display device may include the semiconductor nanoparticle or the light emitting device (e.g., the electroluminescent device and the photoluminescent device).

The semiconductor nanoparticle according to an embodiment can emit a desired range of light, such as blue light, with improved optical properties (e.g., an increased luminous efficiency and a relatively narrow full width at half maximum). The semiconductor nanoparticle of an embodiment can be used as an eco-friendly light-emitting material in a photoluminescent device and an electroluminescent device. The semiconductor nanoparticle of an embodiment may be used in a variety of devices such as TVs, monitors, mobile devices, a VR/AR device, automotive displays, or the like, but embodiments are not limited thereto.

### BRIEF DESCRIPTION OF THE DRAWINGS

The above and other advantages and features of this disclosure will become more apparent by describing in further detail exemplary embodiments thereof with reference to the accompanying drawings.

FIG. 1A is a schematic cross-sectional view of an electronic device (e.g., a display device) including nanocrystal particles according to an embodiment.

FIG. 1B is a schematic cross-sectional view of an electronic device including nanocrystal particles according to an embodiment.

FIG. 1C is a schematic cross-sectional view of an electronic device including nanocrystal particles according to an embodiment.

FIG. 2A schematically shows an exploded view of a device according to an embodiment.

FIG. 2B schematically shows a cross-section of a device according to an embodiment.

FIG. 2C schematically shows a cross-section of a device according to an embodiment.

FIG. 3A shows a UV-Vis absorption spectrum and a photoluminescence spectrum of the semiconductor nanocrystals prepared in Example 2.

FIG. 3B shows a photoluminescence spectrum of the nanoparticles prepared in Example 2.

FIG. 4 shows photoluminescence spectra of the semiconductor nanoparticles prepared in Examples 3 and 5.

### DETAILED DESCRIPTION

Advantages and features of the techniques described hereinafter, and methods of achieving them, will become apparent with reference to the exemplary embodiments described in further detail below and in conjunction with the accompanying drawings. However, the present disclosure should not be construed as being limited to the exemplary embodiments set forth herein. In the drawings, the thickness of layers, films, panels, regions, etc., are exaggerated for clarity. Like reference numerals designate like elements throughout the specification.

If not defined otherwise, all terms (including technical and scientific terms) in the specification may be defined as commonly understood by one skilled in the art. The terms defined in a generally used dictionary may not be interpreted ideally or exaggeratedly unless clearly defined.

It will be further understood that the terms “comprises” and/or “comp rising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the singular forms “a,” “an,” and “the” are intended to include the plural forms, including “at least one,” unless the context clearly indicates otherwise. Therefore, reference to “an” element in a claim followed by reference to “the” element is inclusive of one element as well as a plurality of the elements. For example, the wording “semiconductor nanoparticle” may refer to a single semiconductor nanoparticle or may refer to a plurality of semiconductor nanoparticles. “At least one” is not to be construed as being limited to “a” or “an.” “Or” means “and/or.” As used herein, the term “and/or” includes any and all combinations of one or more of the associated listed items.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, or 5% of the stated value. All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.).

As used herein, the expression “not including cadmium (or other harmful heavy metal)” may refer to the case in which a concentration of cadmium (or other harmful heavy metal) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In an embodiment, substantially no amount of cadmium (or other harmful heavy metal) may be present or, if present, an amount of cadmium (or other harmful heavy metal) may be less than or equal to a detection limit or as an impurity level of a given analysis tool.

As used herein, if a definition is not otherwise provided, “substituted” refers to replacement of at least one hydrogen of a compound or group by a substituent selected from a C1 to C30 alkyl group, a C2 to C30 alkenyl group, a C2 to C30 alkynyl group, a C6 to C30 aryl group, a C7 to C30 alkylaryl group, a C7 to C30 arylalkyl group, a C6 to C30 aryloxy group, a C6 to C30 arylthio group, a C1 to C30 alkoxy group, a C1 to C30 alkylthio group, a C1 to C30 heteroalkyl group, a C3 to C30 heteroaryl group, a C2 to C30 alkylheteroaryl group, a C2 to C30 heteroarylalkyl group, a C1 to C30 heteroaryloxy group, a C1 to C30 heteroarylthio group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group or an amine group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation, a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

In addition, if a definition is not otherwise provided, “hetero” means the case where 1 to 3 heteroatoms selected from N, O, P, Si, S, Se, Ge, and B is or are included.

In addition, the term “aliphatic hydrocarbon group” as used herein refers to a C1 to C30 linear or branched alkyl group, a C1 to C30 linear or branched alkenyl group, or a C1 to C30 linear or branched alkynyl group, and
the term “aromatic organic group” as used herein refers to a C6 to C30 aryl group or a C2 to C30 heteroaryl group.

As used herein, a nanoparticle refers to a structure having at least one region or characteristic dimension with a nanoscale dimension. In an embodiment, the dimension of the nanoparticle or the nanostructure may be less than about 500 nm, less than about 300 nm, less than about 250 nm, less than about 150 nm, less than about 100 nm, less than about 50 nm, or less than about 30 nm. The nanoparticle or nanostructure may have any shape, such as a nanowire, a nanorod, a nanotube, a multi-pod type shape having two or more pods, or a nanodot, but embodiments are not limited thereto. The nanoparticle or nanostructure may be, for example, substantially crystalline, substantially monocrystalline, polycrystalline, amorphous, or a combination thereof.

A quantum dot may be, e.g., a semiconductor-containing nanocrystal particle that can exhibit a quantum confinement effect or an exciton confinement effect, and is a type of a luminescent nanostructure (e.g., capable of emitting light by energy excitation). Herein, a shape of the “quantum dot” or the nanoparticle is not limited unless otherwise defined.

As used herein, the term “dispersion” refers to a dispersion in which a dispersed phase is a solid, and a continuous medium includes a liquid or a solid different from the dispersed phase. Herein, the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm to several micrometers (μm) or less, (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

As used herein, a dimension (a size, a diameter, a thickness, or the like) may be a value for a single entity or an average value for a plurality of entities. As used herein, the term “average” (e.g., an average size of the quantum dot) may be a mean value or a median value. In an embodiment, the average may be a “mean” average.

As used herein, the term “peak emission wavelength” is the wavelength at which a given emission spectrum of the light reaches its maximum.

In an embodiment, a quantum efficiency may be readily and reproducibly determined using commercially available equipment (e.g., from Hitachi or Hamamatsu, etc.) and referring to manuals provided by, for example, respective equipment manufacturers. The quantum efficiency (which can be interchangeably used with the term “quantum yield” (QY)) may be measured in a solution state or a solid state (in a composite). In an embodiment, the quantum efficiency (or the quantum yield) is the ratio of photons emitted to photons absorbed by the nanostructure (or population thereof). In an embodiment, the quantum efficiency may be measured by any suitable method. For example, there may be two methods for measuring the fluorescence quantum yield or efficiency: the absolute method and the relative method. The quantum efficiency measured by the absolute method may be referred to as an absolute quantum efficiency.

In the absolute method, the quantum efficiency may be obtained by detecting the fluorescence of all samples through an integrating sphere. In the relative method, the quantum efficiency of the unknown sample may be calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to their PL wavelengths, but embodiments are not limited thereto.

A full width at half maximum and a peak emission wavelength may be measured, for example, from a luminescence spectrum (for example, a photoluminescence (PL) spectrum or an electroluminescent (EL) spectrum) obtained by a spectrophotometer such as a fluorescence spectrophotometer or the like.

A semiconductor nanoparticle may be included in a variety of electronic devices. An electrical and/or an optical property of the nanoparticle may be controlled for example, by its elemental composition, its size, its shape, or a combination thereof. In an embodiment, the semiconductor nanoparticle may include a semiconductor nanocrystal. The semiconductor nanoparticle such as a quantum dots may have a relatively large surface area per a unit volume, and thus, may exhibit a quantum confinement effect, exhibiting physical properties and optical properties that are different from a corresponding bulk material having the same composition. Therefore, a luminescent nanoparticle such as a quantum dot may absorb energy (e.g., incident light) supplied from an excitation source to form an excited state, which upon relaxation is capable of emitting an energy corresponding to its bandgap energy.

Some semiconductor nanoparticles may show properties (e.g., optical properties and/or stability) applicable to an actual device, but many of them include a cadmium-containing compounds (e.g., cadmium chalcogenide). Cadmium is one of the most restricted elements, and possibly causes a serious environment/health issue. Therefore, in order to develop a cadmium-free environmentally friendly semiconductor nanoparticle, an abundance of in-depth research on a nanocrystal particle including a Group III-V compound or a zinc tellurium selenide has been conducted in this respect. However, most, if not all, known cadmium free nanoparticle will have technological limitations in terms of blue light emission. Therefore, it remains desirable to develop a cadmium-free semiconductor nanoparticle that can emit blue light with a higher light emitting efficiency and a narrower full width at half maximum than a more conventional cadmium-free semiconductor nanoparticle.

For non-cadmium quantum dots, many studies have been conducted on Group 11-13-16 three-component compounds. However, the semiconductor nanoparticles that are based on the group 11-13-16 three-component compounds tend to exhibit a relatively wide emission peak and to exhibit a relatively high intensity (e.g., trap emission) in a longer wavelength range (e.g., a wavelength range of greater than the peak emission wavelength by at least about 60 nm or more). As a result, despite many studies made to date, we are unaware of any reports in regard to a Group 11-13-16 compound based semiconductor nanoparticle that can emit a blue light with a desired wavelength (e.g., less than 490 nm and more than 400 nm, or more than 430 nm), and exhibit desired optical properties (e.g., relatively narrow half width, increased luminous efficiency) together with a reduced trap light emission.

By having the structure/composition described herein, a semiconductor nanoparticle in an embodiment can emit blue light with a desired range of wavelengths and can achieve improved optical properties (e.g., relatively narrow half width, increased (acceptable) quantum yield, and suppressed trap emission). The semiconductor nanoparticle in an embodiment can be used as a downward conversion material in a wide range of applications, such as in a color conversion panel or a color conversion sheet, or in a device such as a panel or a sheet including them and realizing improved photo-conversion in these applications. In the case of semiconductor nanoparticle of an embodiment, light emission (e.g., trap light emission) in an undesired region may be reduced or suppressed.

In an embodiment, a semiconductor nanoparticle includes (a group 11-13-16 compound including) silver, indium, gallium, and sulfur and is configured to emit blue light. The luminescent nanoparticle of an embodiment may include a semiconductor nanocrystal. The semiconductor nanoparticles according to an embodiment may be based on a silver gallium sulfide (e.g., AgGaS₂, bulk bandgap energy of about 2.51 to about 2.73 eV), a silver indium sulfide (e.g., AgInS₂, bulk energy bandgap of about 1.8 eV), or a combination thereof. In an embodiment, a semiconductor nanoparticle may not include cadmium and may be environmentally friendly. In an embodiment, the semiconductor nanoparticle may not include mercury, lead, or a combination thereof.

In a semiconductor nanoparticle of an embodiment, a mole ratio of gallium to a sum of indium and gallium [Ga:(In+Ga)] may be greater than or equal to about 0.81:1, greater than or equal to about 0.83:1, greater than or equal to about 0.85:1, greater than or equal to about 0.86:1, greater than or equal to about 0.87:1, greater than or equal to about 0.88:1, greater than or equal to about 0.89:1, greater than or equal to about 0.9:1, greater than or equal to about 0.91:1, greater than or equal to about 0.92:1, greater than or equal to about 0.93:1, greater than or equal to about 0.94:1, or greater than or equal to about 0.95:1. The mole ratio of gallium to a sum of indium and gallium [Ga:(In+Ga)] may be less than or equal to about 0.995:1, less than or equal to about 0.99:1, less than or equal to about 0.98:1, less than or equal to about 0.97:1, or less than or equal to about 0.968:1. In the semiconductor nanoparticle of an embodiment, a mole ratio of gallium to a sum of indium and gallium [Ga:(In+Ga)] may be greater than or equal to about 0.88:1 and less than or equal to about 0.98:1. In the semiconductor nanoparticle of an embodiment, a mole ratio of gallium to a sum of indium and gallium [Ga:(In+Ga)] may be greater than or equal to about 0.905 and less than or equal to about 0.975:1.

In the semiconductor nanoparticle of an embodiment, a mole ratio of sulfur to a sum of silver, indium, and gallium [S:(Ag+In+Ga)] may be greater than or equal to about 0.5:1, greater than or equal to about 0.65:1, greater than or equal to about 0.7:1, greater than or equal to about 0.76:1, greater than or equal to about 0.8:1, greater than or equal to about 0.87:1, greater than or equal to about 0.9:1, greater than or equal to about 0.91:1, or greater than or equal to about 0.92:1. In the semiconductor nanoparticle of an embodiment, a mole ratio of sulfur to a sum of silver, indium, and gallium [S:(Ag+In+Ga)] may be less than or equal to about 1.35:1, less than or equal to about 1.33:1, less than or equal to about 1.3:1, less than or equal to about 1.25:1, less than or equal to about 1.2:1, or less than or equal to about 1.17:1, less than or equal to about 1.15:1, less than or equal to about 1.09:1, less than or equal to about 1.05:1, or less than or equal to about 1.02:1.

In the semiconductor nanoparticle of an embodiment, a mole ratio of a sum of indium and gallium to silver [(In+Ga):Ag] may be greater than or equal to about 1.9:1, greater than or equal to about 2:1, greater than or equal to about 2.1:1, greater than or equal to about 2.2:1, greater than or equal to about 2.3:1, greater than or equal to about 2.5:1, greater than or equal to about 2.7:1, greater than or equal to about 2.9:1, greater than or equal to about 3:1, or greater than or equal to about 3.2:1. The mole ratio of a sum of indium and gallium to silver [(In+Ga):Ag] may be less than or equal to about 7:1, less than or equal to about 6.3:1, less than or equal to about 5:1, less than or equal to about 4:1, less than or equal to about 3.8:1, less than or equal to about 3.6:1, less than or equal to about 3.5:1, or less than or equal to about 3.1:1.

In the semiconductor nanoparticle of an embodiment, a mole ratio of silver to a sum of silver, indium, and gallium [Ag:(Ag+In+Ga)] may be less than or equal to about 0.5:1, less than or equal to about 0.38:1, less than or equal to about 0.37:1, less than or equal to about 0.35:1, less than or equal to about 0.34:1, less than or equal to about 0.33:1, less than or equal to about 0.32:1, or less than or equal to about 0.31:1. In the semiconductor nanoparticle of an embodiment, the mole ratio of silver to a sum of silver, indium, and gallium [Ag:(Ag+In+Ga)] may be greater than or equal to about 0.09:1, greater than or equal to about 0.1:1, greater than or equal to about 0.12:1, greater than or equal to about 0.13:1, greater than or equal to about 0.15:1, greater than or equal to about 0.2:1, greater than or equal to about 0.25:1, or greater than or equal to about 0.32:1.

In the semiconductor nanoparticle of an embodiment, a mole ratio of indium to sulfur [In:S] may be greater than or equal to about 0.01:1, greater than or equal to about 0.05:1, greater than or equal to about 0.075:1, greater than or equal to about 0.08:1, or greater than or equal to about 0.09:1. The mole ratio of indium to sulfur [In:S] may be less than or equal to about 0.2:1, less than or equal to about 0.17:1, less than or equal to about 0.16:1, less than or equal to about 0.15:1, less than or equal to about 0.1:1, less than or equal to about 0.09:1, less than or equal to about 0.08:1, less than or equal to about 0.075:1, less than or equal to about 0.07:1, less than or equal to about 0.065:1, less than or equal to about 0.06:1, or less than or equal to about 0.055:1.

In the semiconductor nanoparticle of an embodiment, a mole ratio of silver to sulfur [Ag:S] may be greater than or equal to about 0.1:1, greater than or equal to about 0.15:1, greater than or equal to about 0.18:1, greater than or equal to about 0.25:1, or greater than or equal to about 0.3:1. The mole ratio of silver to sulfur [Ag:S] may be less than or equal to about 1:1, less than or equal to about 0.6:1, less than or equal to about 0.5:1, less than or equal to about 0.4:1, less than or equal to about 0.38:1, less than or equal to about 0.36:1, less than or equal to about 0.35:1, less than or equal to about 0.34:1, less than or equal to about 0.32:1, less than or equal to about 0.29:1, or less than or equal to about 0.26:1.

In the semiconductor nanoparticle of an embodiment, a mole ratio of gallium to sulfur (Ga:S) may be greater than or equal to about 0.55:1, greater than or equal to about 0.56:1, greater than or equal to about 0.58:1, greater than or equal to about 0.6:1, greater than or equal to about 0.62:1, greater than or equal to about 0.7:1, greater than or equal to about 0.77:1, greater than or equal to about 0.8:1, or greater than or equal to about 0.82:1. The mole ratio of gallium to sulfur (Ga:S) may be less than or equal to about 1.2:1, less than or equal to about 1.1:1, less than or equal to about 1:1, less than or equal to about 0.95:1, less than or equal to about 0.9:1, less than or equal to about 0.85:1, less than or equal to about 0.84:1, less than or equal to about 0.8:1, less than or equal to about 0.75:1, or less than or equal to about 0.7:1.

In an embodiment, the semiconductor nanoparticle may not include lithium. In an embodiment, the semiconductor nanoparticle may not include an alkali metal such as sodium, potassium, or the like. In an embodiment, the semiconductor nanoparticle may further include or may not include zinc. In an embodiment, the semiconductor nanoparticle may include or may not include selenium.

In the semiconductor nanoparticle of an embodiment, an amount of the indium may have a concentration gradient varying (decreasing) in a radial direction (e.g., from its center to its surface). In the semiconductor nanoparticle of one or more embodiments, an indium amount (or concentration) in a portion adjacent (proximate) to a surface (e.g., an outermost layer or a shell layer) of the semiconductor nanoparticle may be less than an indium amount (or concentration) of an inner portion or a core of the semiconductor nanoparticle. In an embodiment, a portion proximate (or adjacent) to a surface of the particle may not include indium. In the semiconductor nanoparticle of an embodiment, an amount of the zinc may have a concentration gradient varying (for example, increasing) in a radial direction (e.g., from its center to its surface). In the semiconductor nanoparticle of an embodiment, a zinc amount (or concentration) in a portion adjacent (proximate) to a surface (e.g., an outermost layer or a shell layer) of the semiconductor nanoparticle may be greater than a zinc amount (or concentration) of an inner portion or a core of the semiconductor nanoparticle. In an embodiment, an inner portion or a core of the particle may not include zinc.

In an embodiment, the semiconductor nanoparticle may include a first semiconductor nanocrystal and/or a second semiconductor nanocrystal. In an embodiment, the semiconductor nanoparticle may have a core shell structure having a core and a shell disposed on the core. The core may include a first semiconductor nanocrystal. The shell may include a second semiconductor nanocrystal. In the semiconductor nanoparticle, the second semiconductor nanocrystal may be disposed on at least a portion of the first semiconductor nanocrystal. The second semiconductor nanocrystal may surround the first semiconductor nanocrystal. The first semiconductor nanocrystal may have a different composition from the second semiconductor nanocrystal. The first semiconductor nanocrystal may include silver, indium, gallium, and sulfur. The second semiconductor nanocrystal may include gallium, sulfur, and, optionally, silver.

The semiconductor nanoparticle may further include an inorganic layer (for example, including a third semiconductor nanocrystal) including a zinc chalcogenide, for example as an outermost layer thereof. The zinc chalcogenide may include zinc; and selenium, sulfur, or a combination thereof. The zinc chalcogenide may include a zinc sulfide, a zinc selenide, a zinc sulfide selenide, or a combination thereof. A bandgap energy of the second semiconductor nanocrystal may be less than a bandgap energy of the third semiconductor nanocrystal. The second semiconductor nanocrystal may be disposed between the first semiconductor nanocrystal and the inorganic layer.

A size (or average size, hereinafter, can be simply referred to as “size”) of the core or the first semiconductor nanocrystal may be greater than or equal to about 3 nm, greater than or equal to about 3.5 nm, greater than or equal to about 4 nm, greater than or equal to about 4.5 nm, or greater than or equal to about 5 nm. The size of the core or the first semiconductor nanocrystal may be less than or equal to about 8 nm, less than or equal to about 7.5 nm, less than or equal to about 7 nm, less than or equal to about 6.5 nm, less than or equal to about 6 nm, less than or equal to about 5.5 nm, less than or equal to about 5 nm, or less than or equal to about 4.5 nm.

A thickness (or an average thickness, hereinafter, simply referred to as “thickness”) of the second semiconductor nanocrystal may be greater than or equal to about 0.5 nm, greater than or equal to about 1 nm, greater than or equal to about 1.5 nm, or greater than or equal to about 2 nm. The thickness of the shell or the second semiconductor nanocrystal may be less than or equal to about 5 nm, less than or equal to about 4 nm, less than or equal to about 3 nm, less than or equal to about 2.5 nm, less than or equal to about 1.2 nm, or less than or equal to about 0.7 nm.

A thickness of the inorganic layer may be appropriately selected. The thickness of the inorganic layer may be less than or equal to about 5 nm, less than or equal to about 4 nm, less than or equal to about 3.5 nm, less than or equal to about 3 nm, less than or equal to about 2.5 nm, less than or equal to about 2 nm, less than or equal to about 1.5 nm, less than or equal to about 1 nm, or less than or equal to about 0.8 nm. The thickness of the inorganic layer may be greater than or equal to about 0.1 nm, greater than or equal to about 0.3 nm, greater than or equal to about 0.5 nm, or greater than or equal to about 0.7 nm. The thickness of the inorganic layer may be about 0.1 nm to about 5 nm, about 0.3 nm to about 4 nm, about 0.5 nm to about 3.5 nm, about 0.7 nm to about 3 nm, about 0.9 nm to about 2.5 nm, about 1 nm to about 2 nm, about 1.5 nm to about 1.7 nm, or a combination thereof.

The first semiconductor nanocrystal may include silver, a Group 13 metal (e.g., indium, gallium, or a combination thereof), and a chalcogen element (e.g., sulfur, and optionally selenium). The first semiconductor nanocrystal may include a quaternary alloy semiconductor material based on a Group 11-13-16 compound including silver (Ag), indium, gallium, and sulfur. The first semiconductor nanocrystal may include silver indium gallium sulfide, e.g., Ag(InₓGa₁₋ₓ)S₂ (x is greater than or equal to about 0 and less than or equal to about 1). The mole ratios between the components in the first semiconductor nanocrystal may be adjusted so that the final semiconductor nanoparticle may have a desired composition and an optical property (e.g., a peak emission wavelength). The first semiconductor nanocrystal or the core may not include zinc, selenium, or a combination thereof.

The second semiconductor nanocrystal or the shell may include a Group 13 metal (indium, gallium, or a combination thereof), and a chalcogen element (sulfur, and optionally selenium). The second semiconductor nanocrystal or the shell may further include silver (Ag). The second semiconductor nanocrystal or the shell may include silver, gallium, and sulfur. The second semiconductor nanocrystal or the shell may include a ternary alloy semiconductor material including silver, gallium, and sulfur. The second semiconductor nanocrystal or the shell may have a different composition from that of the first semiconductor nanocrystal. The second semiconductor nanocrystal or the shell may include a Group 13-16 compound, a Group 11-13-16 compound, or a combination thereof. The Group 13-16 compound may include gallium sulfide, gallium selenide, indium sulfide, indium selenide, indium gallium sulfide, indium gallium selenide, indium gallium selenide sulfide, or a combination thereof. An energy bandgap of the second semiconductor nanocrystal may be different from that of the first semiconductor nanocrystal. The second semiconductor nanocrystal may cover at least a portion of the first semiconductor nanocrystal. An energy bandgap of the second semiconductor nanocrystal may be greater than an energy bandgap of the first semiconductor nanocrystal. An energy bandgap of the second semiconductor nanocrystal may be less than an energy bandgap of the first semiconductor nanocrystal. The molar ratios between each component in the second semiconductor nanocrystal may be adjusted so that the final semiconductor nanoparticle exhibits a desired composition and optical properties.

The second semiconductor nanocrystal or the first semiconductor nanocrystal may exhibit crystallinity when confirmed by, for example, an appropriate analytical means (e.g., an X-ray diffraction analysis, an electron microscope analysis such as high angle annular dark field (HAADF)-scanning transmission electron microscope (STEM) analysis, or the like).

A size (or an average particle size, hereinafter, simply referred to as “size”) of the semiconductor nanoparticle may be greater than or equal to about 1 nm, greater than or equal to about 1.5 nm, greater than or equal to about 2 nm, greater than or equal to about 2.5 nm, greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, greater than or equal to about 9.5 nm, greater than or equal to about 10 nm, or greater than or equal to about 10.5 nm. The particle size of the semiconductor nanoparticle may be less than or equal to about 50 nm, less than or equal to about 48 nm, less than or equal to about 46 nm, less than or equal to about 44 nm, less than or equal to about 42 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 8 nm, less than or equal to about 6 nm, or less than or equal to about 4 nm.

As used herein, the size of the semiconductor nanoparticle may be a particle diameter or an equivalent diameter. The particle size of the semiconductor nanoparticle may be an equivalent diameter thereof that is obtained by a calculation involving a conversion of a two-dimensional area of a transmission electron microscopy image of a given particle into a circle. The particle size may be a value (e.g., a nominal particle size) calculated from a composition and a peak emission wavelength of the semiconductor nanoparticle.

The semiconductor nanoparticle of an embodiment may be configured to emit blue light of a desired wavelength and having improved properties such as a narrow FWHM, an increased QY, and/or a suppressed trap emission.

A peak emission wavelength of the blue light or the semiconductor nanoparticle may be greater than or equal to about 400 nm, greater than or equal to about 405 nm, greater than or equal to about 410 nm, greater than or equal to about 415 nm, greater than or equal to about 420 nm, greater than or equal to about 425 nm, greater than or equal to about 430 nm, greater than or equal to about 435 nm, greater than or equal to about 440 nm, greater than or equal to about 445 nm, greater than or equal to about 450 nm, greater than or equal to about 455 nm, greater than or equal to about 460 nm, greater than or equal to about 465 nm, greater than or equal to about 470 nm, greater than or equal to about 475 nm, greater than or equal to about 480 nm, or greater than or equal to about 485 nm. The peak emission wavelength of the blue light or he semiconductor nanoparticle may be less than or equal to about 490 nm, less than or equal to about 480 nm, less than or equal to about 475 nm, less than or equal to about 470 nm, less than or equal to about 465 nm, less than or equal to about 460 nm, less than or equal to about 455 nm, less than or equal to about 450 nm, less than or equal to about 445 nm, less than or equal to about 440 nm, less than or equal to about 435 nm, less than or equal to about 430 nm, less than or equal to about 425 nm, less than or equal to about 420 nm, or less than or equal to about 415 nm.

For example, a peak emission wavelength of the blue light or the semiconductor nanoparticle may be greater than or equal to about 410 nm and less than or equal to about 480 nm, greater than or equal to about 420 nm and less than or equal to about 480 nm, greater than or equal to about 430 nm and less than or equal to about 470 nm, or greater than or equal to about 440 nm and less than or equal to about 460 nm.

A full width at half maximum (FWHM) of the first light or a FWHM of the semiconductor nanoparticle may be greater than or equal to about 5 nm, greater than or equal to about 10 nm, greater than or equal to about 15 nm, greater than or equal to about 20 nm, greater than or equal to about 25 nm, or greater than or equal to about 30 nm. The full width at half maximum may be less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 38 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, less than or equal to about 28 nm, less than or equal to about 27 nm, less than or equal to about 26 nm, or less than or equal to about 25 nm.

For example, a FWHM of the first light or a FWHM of the semiconductor nanoparticle may be greater than or equal to about 15 nm and less than or equal to about 60 nm, greater than or equal to about 20 nm and less than or equal to about 50 nm, greater than or equal to about 25 nm and less than or equal to about 45 nm, or greater than or equal to about 30 nm and less than or equal to about 40 nm.

The semiconductor nanoparticle may exhibit a quantum yield of greater than or equal to about 40%. The quantum yield may be an absolute quantum yield. The quantum yield may be greater than or equal to about 45%, greater than or equal to about 46%, greater than or equal to about 49%, greater than or equal to about 50%, greater than or equal to about 55%, greater than or equal to about 60%, greater than or equal to about 65%, greater than or equal to about 70%, greater than or equal to about 75%, greater than or equal to about 80%, greater than or equal to about 85%, greater than or equal to about 90%, or greater than or equal to about 95%. The quantum yield may be in a range of 46%-100%, 49%-99.5%, 60%-99%, 67%-98%, 73%-97%, or a combination thereof.

The blue light may include band-edge emission. In an embodiment, the light emitted by the semiconductor nanoparticle may further include a defect site emission or a trap emission. The band-edge emission may be centered at a higher energy (a lower wavelength) with a smaller offset from the absorption onset energy compared to the trap emission. The band-edge emission may have a narrower wavelength distribution than the trap emission. The band-edge emission may have a normal (e.g., Gaussian) wavelength distribution.

A difference between the band-edge peak emission wavelength and the trap peak emission wavelength may be, for example, greater than or equal to about 60 nm, greater than or equal to about 65 nm, greater than or equal to about 70 nm, greater than or equal to about 75 nm, greater than or equal to about 80 nm, greater than or equal to about 90 nm, or greater than or equal to about 100 nm, and less than or equal to about 150 nm, or less than or equal to about 120 nm.

In a photoluminescence spectrum of the semiconductor nanoparticle, a ratio (percentage) of an area of the tail emission peak (e.g., the peak emission wavelength+at least 70 nm, at least 80 nm, at least 90 nm, or at least 100 nm) to a total area of the emission peak may be less than or equal to about 30%, less than or equal to about 25%, less than or equal to about 22%, less than or equal to about 20%, less than or equal to about 15%, less than or equal to about 12%, less than or equal to about 10%, less than or equal to about 9%, less than or equal to about 8%, less than or equal to about 7%, less than or equal to about 6%, less than or equal to about 5%, less than or equal to about 4%, less than or equal to about 3%, or less than or equal to about 2%.

In the photoluminescence spectrum of the semiconductor nanoparticle, a trap emission value defined by Equation 1 may be less than or equal to about 0.3:

trap emission value=A2/A1 Equation 1

wherein, in Equation 1,
A1 is an intensity at the peak emission wavelength, and
A2 is a maximum intensity in a tail wavelength range of the peak emission wavelength+greater than or equal to 60 nm (for example, greater than or equal to 80 nm, greater than or equal to 90 nm, or greater than or equal to 100 nm).

An upper limit of the wavelength range in A2 or of the tail emission wavelength range may be a wavelength at which an intensity of the spectrum becomes substantially zero. In an embodiment, the wavelength range may be the peak emission wavelength+less than or equal to 200 nm or less than or equal to 120 nm, but is not limited thereto.

The trap emission value may be less than or equal to about 0.28, less than or equal to about 0.25, less than or equal to about 0.22, less than or equal to about 0.2, less than or equal to about 0.19, less than or equal to about 0.18, less than or equal to about 0.17, less than or equal to about 0.16, less than or equal to about 0.15, less than or equal to about 0.14, less than or equal to about 0.13, less than or equal to about 0.12, less than or equal to about 0.11, less than or equal to about 0.1, less than or equal to about 0.09, less than or equal to about 0.08, less than or equal to about 0.07, less than or equal to about 0.06, less than or equal to about 0.05, less than or equal to about 0.04, or less than or equal to about 0.03.

The blue light emitted from a group 13-16 compound-based nanoparticle tends to have a considerable level of trap emission. Without wishing to be bound by any theory, such trap luminescence may be related with the defects on the surface of a semiconductor nanocrystal (e.g., a core) that can act as a light emission center. According to an embodiment, the semiconductor nanoparticle (e.g., manufacturing by a method described herein) can emit blue light with a significantly reduced level of trap emission value.

In an embodiment, a method of producing the semiconductor nanoparticle includes; heating a first reaction solution containing a first metal precursor and a first sulfur precursor to a first reaction temperature for first reaction time to obtain a semiconductor nanocrystal, and reacting a second metal precursor and a second sulfur precursor in an organic solvent in the presence of the semiconductor nanocrystal to synthesize the semiconductor nanoparticle,
wherein the first metal precursor includes a first silver compound, a first gallium compound, and a first indium compound, and the second metal precursor includes a second gallium compound and, optionally, a second silver compound, and
wherein in the first reaction solution, a mole ratio of gallium to indium may be greater than or equal to about 3.5:1, and the first reaction temperature may be greater than or equal to about 240° C., for example, greater than or equal to about 245° C. The first reaction temperature may be less than or equal to about 300° C.

In an embodiment, the first reaction solution may be thermally treated continuously (e.g., in a single step) from an initial temperature (e.g., a temperature of from about 40° C. to about 60° C.) to the first reaction temperature. The preparation of the first reaction solution may include a vacuum treatment for a reaction reagent (e.g., a precursor, an organic solvent, an organic ligand) or a mixture thereof. The vacuum treatment may be conducted at room temperature or at a higher temperature (e.g., greater than or equal to about 30° C., greater than or equal to about 40° C., greater than or equal to about 60° C., and less than or equal to about 200° C., less than or equal to about 150° C., less than or equal to about 130° C., less than or equal to about 120° C., less than or equal to about 100° C., etc.).

In an embodiment, the first reaction solution may not contain a selenium compound. Examples of the selenium compound are as described herein. In an embodiment, the first reaction solution may not contain a zinc precursor. Examples of the zinc precursor are as described herein.

Many studies have been conducted on semiconductor nanocrystals based on group 11-13-16 compounds, but those studies have yet to report how to actually make or obtain semiconductor nanocrystals based on group 11-13-16 compounds that emit blue light and exhibit relatively narrow FWHM and increased luminous efficiency. In the case of the semiconductor nanocrystals (or the core) based on group 11-13-16 compounds that are prepared according to a conventional known method, the emission spectrum of such nanocrystals hardly exhibit a band-edge emission peak in the blue light emission wavelength range. Without wishing to be bound by any theory, it is believed that the 11-13-16 semiconductor nanocrystal (e.g., the core) prepared by conventional methods include various trap levels resulting from the defects, for example, surface defects, which make the trap emission predominant in the spectrum of the light emitted by the semiconductor nanocrystal.

Surprisingly, the present inventors have found that by developing and adopting the method of preparation described herein (e.g., by heating the first reaction solution at the first reaction temperature to conduct a reaction, for example, in accordance with the method described herein), a semiconductor nanocrystal can be obtained that exhibits a relatively distinct band-edge emission peak in the blue light region. Moreover, by the adoption of a subsequent reaction between the second precursors in the presence of the semiconductor nanocrystal, a resulting luminescent semiconductor nanoparticle can exhibit the properties described herein.

In the first reaction solution, a mole ratio of gallium to indium (Ga:In) may be greater than about 3.1:1, greater than or equal to about 3.2:1, greater than or equal to about 3.5:1, greater than or equal to about 4:1, greater than or equal to about 4.5:1, greater than or equal to about 5:1, greater than or equal to about 5.5:1, greater than or equal to about 6:1, greater than or equal to about 6.5:1, or greater than or equal to about 7:1. In the first reaction solution, a mole ratio of gallium to indium (Ga:In) may be less than or equal to about 20:1, less than or equal to about 15:1, or less than or equal to about 10:1.

In the first reaction solution, a mole ratio between the precursors or a mole ratio between the compounds may be controlled (determined) to provide a semiconductor nanocrystal having a desired elemental composition. In an embodiment, the mole ratio between the first metal precursor and the sulfur precursor of the first reaction solution may be adjusted to obtain a desired composition of the semiconductor nanocrystal.

In the method of an embodiment, (in the first metal precursors) an amount of the silver precursor per one mole of indium may be greater than or equal to about 1 mole, greater than or equal to about 1.2 moles, greater than or equal to about 1.4 moles, or greater than or equal to about 2 moles, and less than or equal to about 10 moles, less than or equal to about 7 moles, less than or equal to about 5 moles, or less than or equal to about 4.5 moles.

In the preparation of a semiconductor nanocrystal according to an embodiment, an amount of the sulfur precursor per one mole of indium may be greater than or equal to about 0.5 moles, greater than or equal to about 1 moles, greater than or equal to about 1.5 moles, greater than or equal to about 2 moles, greater than or equal to about 2.5 moles, greater than or equal to about 3 moles, greater than or equal to about 3.5 moles, greater than or equal to about 4 moles, greater than or equal to about 4.5 moles, greater than or equal to about 5 moles, greater than or equal to about 6 moles, greater than or equal to about 6.5 moles, greater than or equal to about 8 moles, greater than or equal to about 9 moles, greater than or equal to about 11 moles, greater than or equal to about 13 moles, or greater than or equal to about 15 moles.

In the embodiment, an amount of the sulfur precursor per one mole of indium may be less than or equal to about 25 moles, less than or equal to about 20 moles, less than or equal to about 15 moles, less than or equal to about 10 moles, less than or equal to about 8 moles, less than or equal to about 6 moles, less than or equal to about 4 moles, or less than or equal to about 2 moles.

In the method of an embodiment, a mole ratio of the silver precursor to a sum of the moles of the used indium precursor and the used gallium precursor may be greater than or equal to about 0.1:1, greater than or equal to about 0.2:1, greater than or equal to about 0.24:1, greater than or equal to about 0.25:1, or greater than or equal to about 0.26:1. The mole ratio of the silver precursor to a sum of the moles of the used indium precursor and the used gallium precursor may be less than or equal to about 2:1, less than or equal to about 1.5:1, less than or equal to about 1:1, or less than or equal to about 0.5:1.

A mole ratio of the first sulfur precursor to a sum of the used moles of the first metal precursors (e.g., the silver compound, the indium compound, and the gallium compound) may be greater than or equal to about 1:1, greater than or equal to about 1.2:1, or greater than or equal to about 1.5:1 and less than or equal to about 5:1, less than or equal to about 4:1, less than or equal to about 3:1, less than or equal to about 2:1, less than or equal to about 1.8:1, less than or equal to about 1.5:1, or less than or equal to about 1.45:1.

The first reaction temperature may be greater than or equal to about 250° C. or greater than or equal to about 255° C. The first reaction temperature may be less than or equal to about 295° C., less than or equal to about 290° C., less than or equal to about 285° C., less than or equal to about 280° C., less than or equal to about 275° C., less than or equal to about 270° C., or less than or equal to about or 265° C.

The reaction time at the first reaction temperature may be greater than or equal to about 10 minutes, greater than or equal to about 15 minutes, greater than or equal to about 20 minutes, greater than or equal to about 25 minutes, greater than or equal to about 30 minutes, greater than or equal to about 35 minutes. The reaction time at the first reaction temperature may be less than or equal to about 200 minutes, less than or equal to about 150 minutes, less than or equal to about 120 minutes, less than or equal to about 100 minutes, less than or equal to about 90 minutes, less than or equal to about 80 minutes, less than or equal to about 75 minutes, less than or equal to about 70 minutes, less than or equal to about 65 minutes, less than or equal to about 60 minutes, less than or equal to about 55 minutes, or less than or equal to about or 50 minutes.

The method may include or may not include the further addition of an organic ligand compound, (e.g., a phosphine compound such as trioctyl phosphine) to a reaction medium after the reaction at the first reaction temperature.

In an embodiment, the semiconductor nanocrystal (e.g., the core) may be separated from the reaction system after the synthesis reaction. The separation and recovery of the semiconductor nanocrystal can be conducted in the manner described herein.

In an embodiment, the semiconductor nanocrystal obtained from the first reaction solution may exhibit a first emission peak in a range of less than or equal to about 500 nm.

In an embodiment, the semiconductor nanocrystal may further exhibit a second emission peak in a range of greater than or equal to about 500 nm. Without wishing to be bound by any theory, the first emission peak may correspond to a band edge emission, and the second emission peak may correspond to a trap emission. In an embodiment, an intensity of the first emission peak may be greater than an intensity of the second emission peak. An intensity ratio of the first emission peak to the second emission peak may be greater than about 1:1, greater than or equal to about 1.1:1, greater than or equal to about 1.2:1, greater than or equal to about 1.3:1, or greater than or equal to about 1.4:1. An intensity ratio of the first emission peak to the second emission peak may be less than or equal to about 3:1, less than or equal to about 2.5:1, less than or equal to about 2:1, less than or equal to about 1.5:1.

In an embodiment, the intensity of the first emission peak may be lower than the intensity of the second emission peak. An intensity ratio of the second emission peak to the first emission peak may be greater than about 1, greater than or equal to about 1.1:1, greater than or equal to about 1.2:1, or greater than or equal to about 1.3:1. An intensity ratio of the second emission peak to the first emission peak may be less than or equal to about 3:1, less than or equal to about 2.5:1, less than or equal to about 2:1, or less than or equal to about 1.5:1.

In an embodiment, the intensity of the first emission peak may be substantially the same as the intensity of the second emission peak.

The second metal precursor and the second sulfur precursor are contacted and heated (e.g., reacted) in an organic solvent in the presence of the semiconductor nanocrystal to synthesize the semiconductor nanoparticle. The second metal precursor includes a second gallium compound and, optionally, a second silver compound.

The reacting of the second metal precursor and the second sulfur precursor may include:
preparing a reaction medium containing the second sulfur precursor and the organic ligand in an organic solvent;
heating the reaction medium to an addition temperature;
adding the semiconductor nanocrystal and the second metal precursor to the reaction medium to obtain a reaction mixture;
heating the reaction mixture to a second reaction temperature for a second reaction time, wherein the addition temperature above may be greater than or equal to about 120° C. and less than or equal to about 280° C., the second reaction temperature may be greater than or equal to about 180° C. and less than or equal to about 380° C. The addition temperature and the second reaction temperature may be the same or different. The second reaction temperature may be higher than the addition temperature.

A difference between the addition temperature and the second reaction temperature may be greater than or equal to about 10° C., greater than or equal to about 20° C., greater than or equal to about 30° C., greater than or equal to about 40° C., greater than or equal to about 50° C., greater than or equal to about 60° C., greater than or equal to about 70° C., greater than or equal to about 80° C., greater than or equal to about 90° C., or greater than or equal to about 100° C. The difference between the addition temperature and the second reaction temperature may be less than or equal to about 200° C., less than or equal to about 190° C., less than or equal to about 180° C., less than or equal to about 170° C., less than or equal to about 160° C., less than or equal to about 150° ° C., less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 50° C., less than or equal to about 40° C., less than or equal to about 30° C., or less than or equal to about or 20° C.

The addition temperature may be greater than or equal to about 120° C., greater than or equal to about 200° C., greater than or equal to about 210° C., greater than or equal to about 220° C., greater than or equal to about 230° C., greater than or equal to about 240° C., or greater than or equal to about or 250° C. The addition temperature may be less than or equal to about 280° C., less than or equal to about 275° C., less than or equal to about 270° C., less than or equal to about 265° C., less than or equal to about 260° C., less than or equal to about 255° C., less than or equal to about 250° C., less than or equal to about 240° C., less than or equal to about 230° C., less than or equal to about 220° C., less than or equal to about 210° C., less than or equal to about 200° C., less than or equal to about 190° C., less than or equal to about 180° C., less than or equal to about 170° C., less than or equal to about 160° C., or less than or equal to about 150° C.

The second reaction temperature may be greater than or equal to about 180° C., greater than or equal to about 240° C., greater than or equal to about 245° C., greater than or equal to about 250° C., greater than or equal to about 255° C., greater than or equal to about 260° C., greater than or equal to about 265° C., greater than or equal to about 270° C., greater than or equal to about 275° C., greater than or equal to about 280° C., greater than or equal to about 285° C., greater than or equal to about 290° C., greater than or equal to about 295° C., greater than or equal to about 300° C., greater than or equal to about 305° C., greater than or equal to about 310° C., greater than or equal to about 315° C., greater than or equal to about 320° ° C., greater than or equal to about 330° C., greater than or equal to about 335° C., greater than or equal to about 340° ° C., or greater than or equal to about 345° C. The second temperature may be less than or equal to about 380° C., less than or equal to about 375° C., less than or equal to about 370° C., less than or equal to about 365° C., less than or equal to about 360° C., less than or equal to about 355° C., less than or equal to about 350° C., less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., less than or equal to about 260° C., or less than or equal to about 250° C.

In an embodiment, the second reaction time may be about 1 minute to about 240 minutes, about 5 minutes to about 200 minutes, about 10 minutes to about 3 hours, about 20 minutes to about 150 minutes, about 30 minutes to about 100 minutes, or a combination thereof.

The method of an embodiment may further include preparing an additional reaction medium containing an organic ligand and a zinc precursor in an organic solvent; heating the additional reaction medium to a reaction temperature; adding the formed semiconductor nanoparticle and a chalcogen precursor to the additional reaction medium to provide an outer layer (e.g., an inorganic layer) containing zinc chalcogenides on the surface of the nanoparticles, for example as an outermost layer. The chalcogen precursor may include a sulfur compound, a selenium compound, or a combination thereof.

The first silver compound and the second silver compound (hereinafter, referred to as the silver precursor or the silver compound), the first gallium compound and the second gallium compound (hereinafter, referred to as the gallium precursor or the gallium compound), the indium compound, and the first sulfur precursor and the second sulfur precursor (hereinafter, referred to as the sulfur precursor or the sulfur compound) are the same as described herein.

The silver compound may include a silver powder, an alkylated silver compound, a silver alkoxide, a silver carboxylate, a silver acetylacetonate, a silver nitrate, a silver sulfate, a silver halide, a silver cyanide, a silver hydroxide, a silver oxide, a silver peroxide, a silver carbonate, or a combination thereof. For example, the silver compound may include a silver nitrate, a silver acetate, a silver acetylacetonate, a silver chloride, a silver bromide, a silver iodide, or a combination thereof.

The indium compound may include an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, an indium acetate, or a combination thereof. For example, the indium compound may include an indium carboxylate such as indium oleate or indium myristate, an indium acetate, an indium hydroxide, an indium halide (indium chloride, an indium bromide, or an indium iodide), or a combination thereof. In an embodiment, the indium compound may include an indium halide (or an indium chloride).

The gallium compound may include a gallium powder, an alkylated gallium compound, a gallium alkoxide, a gallium carboxylate, a gallium nitrate, a gallium perchlorate, a gallium sulfate, a gallium acetylacetonate, a gallium halide, a gallium cyanide, a gallium hydroxide, a gallium oxide, a gallium peroxide, a gallium carbonate, or a combination thereof. For example, the gallium compound may include a gallium chloride, a gallium iodide, a gallium bromide, a gallium acetate, a gallium acetylacetonate, a gallium oleate, a gallium palmitate, a gallium stearate, a gallium myristate, a gallium hydroxide, or a combination thereof. In an embodiment, the first gallium compound may contain gallium acetylacetonate and the second gallium compound may contain gallium chloride.

In an embodiment, the first gallium compound may include a gallium acetylacetonate, the second gallium compound may include a gallium halide, and the first silver compound may include a silver carboxylate (e.g., silver acetate), and the first indium compound may include an indium halide.

A type of the sulfur precursor is not particularly limited and may be appropriately selected. The sulfur precursor may be an organic solvent dispersion or a reaction product of sulfur and an organic solvent, for example, a sulfur-octadecene (S-ODE), a sulfur-trioctylphosphine (S-TOP), a sulfur-tributylphosphine (S-TBP), a sulfur-triphenylphosphine (S-TPP), a sulfur-trioctylamine (S-TOA), a bis(trimethylsilylalkyl) sulfide, a bis(trimethylsilyl) sulfide, a mercapto propyl silane, an ammonium sulfide, a sodium sulfide, a C1-30 thiol compound (e.g., α-toluene thiol, octane thiol, dodecanethiol, octadecene thiol, or the like), an isothiocyanate compound (e.g., cyclohexyl isothiocyanate or the like), an alkylenetrithiocarbonate (e.g., ethylene trithiocarbonate or the like), allyl mercaptan, a thiourea compound (e.g., (di)alkyl thiourea having a C1 to C40 alkyl group, for example, methylthiourea, dimethyl thiourea, ethyl thiourea, diethyl thiourea, ethyl methyl thiourea, dipropyl thiourea, or the like; or an arylthiourea such as a phenyl thiourea), or a combination thereof. In an embodiment, the first sulfur precursor may contain an organic solvent dispersion of sulfur (e.g., a reaction product therebetween), and the second sulfur precursor may contain a thiourea compound.

The selenium compound may include selenium-trioctylphosphine (Se-TOP), selenium-tributylphosphine (Se-TBP), selenium-triphenylphosphine (Se-TPP), or a combination thereof.

A type of the zinc precursor is not particularly limited and may be appropriately selected. In an embodiment, the zinc precursor may include a Zn metal powder, an alkylated Zn compound, a Zn alkoxide, a Zn carboxylate, a Zn nitrate, a Zn perchlorate, a Zn sulfate, a Zn acetylacetonate, a Zn halide, a Zn cyanide, a Zn hydroxide, a Zn oxide, a Zn peroxide, or a combination thereof. The zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The organic ligand may include RCOOH, RNH₂, R₂NH, R₃N, RSH, RH₂PO, R₂HPO, R₃PO, RH₂P, R₂HP, R₃P, ROH, RCOOR′, RPO (OH)₂, RHPOOH, R₂POOH, or a combination thereof (wherein, R and R′ are each independently substituted or unsubstituted C1 to C40 (or C3 to C24) aliphatic hydrocarbon group (e.g., alkyl group, alkenyl group, or alkynyl group), or a substituted or unsubstituted C6 to C40 (or a C6 to C24) aromatic hydrocarbon group (e.g., a C6 to C20 aryl group)). The organic ligand may be bound to the surface of the nanoparticles. Non-limiting examples of the organic ligand may include methane thiol, ethane thiol, propane thiol, butane thiol, pentane thiol, hexane thiol, heptane thiol, octane thiol, nonanethiol, decanethiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methyl phosphine (e.g., trimethyl phosphine, methyldiphenyl phosphine, or the like), substituted or unsubstituted ethyl phosphine (e.g., triethyl phosphine, ethyldiphenyl phosphine, or the like), substituted or unsubstituted propyl phosphine, substituted or unsubstituted butyl phosphine, substituted or unsubstituted pentyl phosphine, substituted or unsubstituted octylphosphine (e.g., trioctylphosphine (TOP)); or the like; a phosphine oxide such as substituted or unsubstituted methyl phosphine oxide (e.g., trimethyl phosphine oxide, methyldiphenylphosphine oxide, or the like), substituted or unsubstituted ethyl phosphine oxide (e.g., triethyl phosphine oxide, ethyldiphenyl phosphine oxide, or the like), substituted or unsubstituted propyl phosphine oxide, substituted or unsubstituted butyl phosphine oxide, substituted or unsubstituted octylphosphine oxide (e.g., trioctylphosphine oxide (TOPO), or the like); diphenyl phosphine, a triphenyl phosphine compound, or an oxide compound thereof; a C5 to C20 alkylphosphinic acid or a C5 to C20 alkyl phosphonic acid such as pentyl phosphonic acid, hexylphosphinic acid, octylphosphinic acid, dodecanephosphinic acid, tetradecanephosphinic acid, hexadecanephosphinic acid, octadecanephosphinic acid, or the like, but embodiments are not limited thereto. The organic ligand may be used alone or as a mixture of two or more.

The organic solvent may include an amine solvent (e.g., an aliphatic amine for example, a C1 to C50 aliphatic amine), a nitrogen-containing heterocyclic compound such as pyridine; a C6 to C40 aliphatic hydrocarbon (e.g., alkane, alkene, alkyne, or the like) such as hexadecane, octadecane, octadecene, or squalene; a C6 to C30 aromatic hydrocarbon such as phenyldodecane, phenyltetradecane, phenyl hexadecane, or the like; a phosphine substituted with a C6 to C22 alkyl group such as trioctylphosphine; a phosphine oxide substituted with a C6 to C22 alkyl group such as trioctylphosphine oxide, or the like; a C12 to C22 aromatic ether such as phenyl ether, or benzyl ether, or the like; or a combination thereof. The amine solvent may be a compound having one or more (e.g., two or three) C1-50, C2-45, C3-40, C4-35, C5-30, C6-25, C7-20, C8-15, or C6-22 aliphatic hydrocarbon groups (alkyl group, alkenyl group, or alkynyl group). In an embodiment, the amine solvent may be a C6-30 primary amine such as hexadecyl amine and oleylamine; secondary amines of C6-30 such as dioctyl amine or the like; C6-30 tertiary amines such as trioctylamine or the like; or a combination thereof.

Amounts of the organic ligand and the precursors in the reaction medium may be selected appropriately in consideration of the type of solvent, the type of the organic ligand and each precursor, and the size and composition of desired particles. Mole ratios between the precursors may be changed taking into consideration the desired mole ratios in the final nanoparticle, the reactivities among the precursors, or the like. In an embodiment, a manner of adding each of the precursors is not particularly limited. In an embodiment, a total amount of a precursor may be added at one time. In an embodiment, a total amount of a precursor may be divided into greater than or equal to about 2 aliquots and less than or equal to about 10 aliquots and added. The precursors may be added simultaneously or sequentially in a predetermined order. The reaction may be carried out in an inert gas atmosphere, in air, or in a vacuum state, but embodiments are not limited thereto.

In an embodiment, after the completion of the reaction, a nonsolvent may be added to a final reaction solution to facilitate separation (e.g., precipitation) of a semiconductor nanoparticle as synthesized (for example, with a coordinating organic ligand). The nonsolvent may be a polar solvent that is miscible with the solvent used in the reaction, but cannot disperse the nanocrystals. The nonsolvent may be selected depending on the solvent used in the reaction and may be for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof. The separation may be performed by centrifugation, precipitation, chromatography, or distillation. Separated nanocrystals may be washed by adding to a washing solvent as needed. The washing solvent is not particularly limited, and a solvent having a solubility parameter similar to that of the organic solvent or ligand may be used. The nonsolvent or washing solvent may be an alcohol; an alkane solvent such as hexane, heptane, octane, or the like; chloroform; an aromatic solvent such as toluene, benzene, or the like; or a combination thereof, but embodiments are not limited thereto.

The semiconductor nanoparticle thus prepared may be dispersed in a dispersion solvent. The semiconductor nanoparticle thus prepared may form an organic solvent dispersion. The organic solvent dispersion may not include water and/or an organic solvent miscible with water. The dispersion solvent may be appropriately selected. The dispersion solvent may include the aforementioned organic solvent. The dispersion solvent may include a substituted or unsubstituted C1 to C40 aliphatic hydrocarbon, a substituted or unsubstituted C6 to C40 aromatic hydrocarbon, or a combination thereof.

A shape of the semiconductor nanoparticle thus prepared is not particularly limited, and may include, for example, spherical, polyhedral, pyramidal, multipod, cubic, nanotubes, nanowires, nanofibers, nanosheets, or a combination thereof, but embodiments are not limited thereto.

The semiconductor nanoparticle of one or more embodiments may include an organic ligand and/or an organic solvent on a surface of the semiconductor nanoparticle. The organic ligand and/or the organic solvent may be bound to a surface of the semiconductor nanoparticle of one or more embodiments.

An embodiment is directed to an ink composition including a liquid vehicle and the semiconductor nanoparticle as described herein. The semiconductor nanoparticle may be dispersed in the liquid vehicle. The liquid vehicle may include a liquid monomer, an organic solvent, or a combination thereof. The ink composition may further include a metal oxide fine particle, for example, dispersed in the liquid vehicle. The ink composition may further include a dispersant (for dispersing the semiconductor nanoparticles and/or the metal oxide fine particle). The dispersant may include a carboxylic acid group-containing organic compound (monomer or polymer). The liquid vehicle may not include an (e.g., volatile) organic solvent. The ink composition may be a solvent-free system.

Details of the semiconductor nanoparticle in the composition (or in the composite) are as described herein. An amount of the semiconductor nanoparticle in the composition or in the composite may be appropriately adjusted taking into consideration a desired end use (for example, a use as a luminescent type color filter). In an embodiment, an amount of the semiconductor nanoparticle in the composition (or composite) may be greater than or equal to about 1 weight percent (wt %), for example, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, or greater than or equal to about 40 wt %, based on the solid content of the composition or composite (hereinafter, the solid content may be a solid content of the composition or a solid content of the composite). The amount of the semiconductor nanoparticle may be less than or equal to about 100 wt %, less than or equal to about 95 wt %, less than or equal to about 70 wt %, less than or equal to about 65 wt %, less than or equal to about 60 wt %, less than or equal to about 55 wt %, or less than or equal to about 50 wt %, based on the solid content. A weight percentage of a given component with respect to a total solid content in a composition may represent an amount of the given component in the composite as described herein.

In an embodiment, an ink composition may be a semiconductor nanoparticle-containing composition capable of providing a pattern in a printing process (e.g., a droplet discharging method such as an inkjet printing). According to an embodiment, the ink composition may be a nanoparticle-containing photoresist composition applicable to a photolithography process. The liquid monomer may include a (photo)polymerizable monomer including a carbon-carbon double bond. The composition may optionally further include a thermal initiator or a photoinitiator. The polymerization of the composition may be initiated by light or heat. The initiator is a compound accelerating a radical reaction (e.g., radical polymerization of monomer) by producing radical chemical species under a mild condition (e.g., by heat or light). The initiator may be a thermal initiator or a photoinitiator. The initiator is not particularly limited and may be appropriately selected.

In the composition (or the liquid vehicle), a liquid monomer or a polymerizable (e.g., photopolymerizable) monomer (hereinafter, referred to as a monomer) including the carbon-carbon double bond may include a (e.g., photopolymerizable) (meth)acryl-containing monomer. The monomer may be a precursor for an insulating polymer.

The metal oxide fine particle may include TiO₂, SiO₂, BaTiO₃, Ba₂TiO₄, ZnO, or a combination thereof. In the composition (or composite), an amount of the metal oxide fine particle may be greater than or equal to about 1 wt %, greater than or equal to about 2 wt %, greater than or equal to about 3 wt %, greater than or equal to about 5 wt %, or greater than or equal to about 10 wt % to less than or equal to about 50 wt %, less than or equal to about 40 wt %, less than or equal to about 30 wt %, less than or equal to about 25 wt %, less than or equal to about 20 wt %, less than or equal to about 15 wt %, less than or equal to about 10 wt %, less than or equal to about 7 wt %, less than or equal to about 5 wt %, or less than or equal to about 3 wt %, based on the total solid content.

A diameter of the metal oxide fine particle is not particularly limited and may be appropriately selected. The diameter of the metal oxide fine particle may be greater than or equal to about 100 nm, for example greater than or equal to about 150 nm, or greater than or equal to about 200 nm and less than or equal to about 1000 nm, or less than or equal to about 800 nm.

The composition or the liquid vehicle may include an organic solvent. The composition or the liquid vehicle may not include an organic solvent. If present, the type of solvent that may be used is not particularly limited. The type and amount of the organic solvent is appropriately determined in consideration of the types and amounts of the aforementioned main components (i.e., nanoparticles, dispersants, polymerizable monomers, initiators, thiol compounds, or the like, if present) and other additives to be described herein. The composition may include a solvent in a residual amount except for a desired content of the (non-volatile) solid. In an embodiment, examples of the organic solvent may be an ethylene glycol solvent such as ethylene glycol, diethylene glycol, polyethylene glycol, and the like; a glycol ether solvent such as ethylene glycol monomethyl ether, ethylene glycol monoethyl ether, diethylene glycol monomethyl ether, ethylene glycol diethyl ether, diethylene glycol dimethyl ether, or the like; a glycol (ether) acetate solvent such as ethylene glycol acetate, ethylene glycol monomethylether acetate, diethylene glycol monomethylether acetate, diethylene glycol monobutylether acetate, or the like; a propylene glycol solvent such as propylene glycol, or the like; a propylene glycol ether solvent such as propylene glycol monomethyl ether, propylene glycol monoethyl ether, propylene glycol monopropyl ether, propylene glycol monobutyl ether, propylene glycol dimethylether, dipropylene glycol dimethyl ether, propylene glycol diethyl ether, dipropylene glycol diethyl ether, or the like; a propylene glycol ether acetate solvent such as propylene glycol monomethyl ether acetate, dipropylene glycol monoethyl ether acetate, or the like; an amide solvent such as N-methylpyrrolidone, dimethyl formamide, dimethyl acetamide, or the like; a ketone solvent such as methylethylketone (MEK), methylisobutylketone (MIBK), cyclohexanone, or the like; a petroleum solvent such as toluene, xylene, solvent naphtha, and the like; an ester solvent such as ethyl acetate, butyl acetate, ethyl lactate, ethyl 3-ethoxy propionate, or the like; an ether solvent such as diethyl ether, dipropyl ether, dibutyl ether, or the like; chloroform; a C1 to C40 aliphatic hydrocarbon (e.g., alkane, alkene, or alkyne), a halogen (e.g., chloro) substituted C1 to C40 aliphatic hydrocarbon (e.g., dichloroethane, trichloromethane, or the like), a C6 to C40 aromatic hydrocarbon (e.g., toluene, xylene, or the like), a halogen (e.g., chloro) substituted C6 to C40 aromatic hydrocarbon; or a combination thereof.

In an embodiment, the ink composition may provide, for example, an emission layer including the semiconductor nanoparticle described herein in an electroluminescent device. In an embodiment, the ink composition may provide a semiconductor nanoparticle-polymer composite including a polymer matrix and the semiconductor nanoparticle dispersed therein or a pattern of the composite, for example, through a process involving a polymerization.

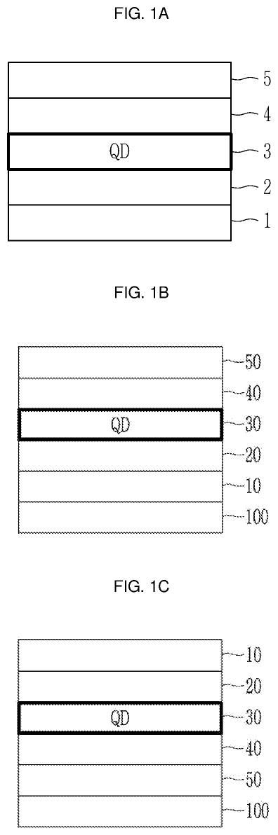

An embodiment provides an electroluminescent device including the aforementioned semiconductor nanoparticle. The electroluminescent device includes a first electrode 1 and a second electrode 5 spaced apart (e.g., facing each other); and, a light emitting layer 3 that is disposed between the first electrode and the second electrode and does not include cadmium (See FIG. 1A). The first electrode may include an anode, and the second electrode may include a cathode. Alternatively, the first electrode may include a cathode and the second electrode may include an anode. The electroluminescent device may further include a hole auxiliary layer 2 between the light emitting layer and the first electrode. The electroluminescent device may further include an electron auxiliary layer 4 between the light emitting layer and the second electrode. The light emitting layer may include the semiconductor nanoparticle. Details of the semiconductor nanoparticle are the same as described above.

In the electroluminescent device, the first electrode 10 or the second electrode 50 may be disposed on a (transparent) substrate 100. The transparent substrate may be a light extraction surface. (See FIGS. 1B and 1C)

Referring to FIGS. 1B and 1C, the light emitting layer 30 may be disposed between the first electrode (e.g., anode) 10 and the second electrode (e.g., cathode) 50. The second electrode or cathode 50 may include an electron injection conductor. The first electrode or anode 10 may include a hole injection conductor. The work function of the electron/hole injection conductor included in the second electrode and the first electrode may be appropriately adjusted and are not particularly limited. For example, the second electrode may have a small work function, and the first electrode may have a relatively large work function, or vice versa.

The electron/hole injection conductors may include a metal-based material (e.g., a metal, a metal compound, an alloy, or a combination thereof) (aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode and/or the second electrode may be a light-transmitting electrode or a transparent electrode. In an embodiment, both the first electrode and the second electrode may be a light-transmitting electrode. The electrode(s) may be patterned. The first electrode and/or the second electrode may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and for example, less than or equal to about 99%, or less than or equal to about 95%).

The substrate may further include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode. The light-transmitting electrode may be disposed on a (e.g., insulating) transparent substrate. The substrate may be rigid or flexible. The substrate may be plastic, glass, or a metal.

The light-transmitting electrode may be made of, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a metal thin film of a single layer or a plurality of layers but is not limited thereto. In an embodiment, either the first electrode or the second electrode may be an opaque electrode, and the electrode may include an opaque conductor such as aluminum (Al), a lithium-aluminum (Li:Al) alloy, a magnesium-silver alloy (Mg:Ag), and lithium fluoride-aluminum (LiF:Al).

A thickness of the electrode (the first electrode and/or the second electrode) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 μm, for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

A light emitting layer 3 or 30 is disposed between the first electrode 1 and the second electrode 5 (e.g., the anode 10 and the cathode 50). The light emitting layer includes nanocrystal particle(s) (e.g., blue light emitting nanoparticles, red light emitting nanoparticles, or green light emitting nanoparticles). The light emitting layer may include one or more (e.g., 2 or more or 3 or more and 10 or less) monolayers of a plurality of nanoparticles.

The light emitting layer may be patterned. In an embodiment, the patterned light emitting layer may include a blue light emitting layer (e.g., disposed within a blue pixel in a display device to be described later), a red light emitting layer (e.g., disposed within a red pixel in a display device to be described later), and a green light emitting layer (e.g., disposed within a green pixel in a display device to be described later), or a combination thereof. Each of the light emitting layers may be (e.g., optically) separated from an adjacent light emitting layer by a partition wall. In an embodiment, partition walls such as black matrices may be disposed between the red light emitting layer(s), the green light emitting layer(s), and the blue light emitting layer(s). The red light emitting layer, the green light emitting layer, and the blue light emitting layer may be optically isolated from each other.

In the light emitting device, the thickness of the light emitting layer may be appropriately selected. In an embodiment, the light emitting layer may include a monolayer(s) of nanoparticles. In another embodiment, the light emitting layer may include one or more monolayers of nanoparticles, for example two or more, three or more, or four or more and 20 or less, 10 or less, 9 or less, 8 or less, 7 or less, or 6 or less. The light emitting layer may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example, about 10 nm to about 150 nm, for example about 20 nm to about 100 nm, for example about 30 nm to about 50 nm.

The forming of the light emitting layer may performed by obtaining a composition including nanoparticles (configured to emit desired light) and applying it on a substrate or charge auxiliary layer in an appropriate manner (e.g., by spin coating, inkjet printing, etc.) or by depositing.

The electroluminescent device may include a charge (hole or electron) auxiliary layer between the first electrode and the second electrode (e.g., the anode and the cathode). For example, in the electroluminescent display device, the hole auxiliary layer 20 or the electron auxiliary layer 40 may be disposed between the first electrode 10 and the light emitting layer 30 and/or between the second electrode 50 and the light emitting layer 30. (See FIGS. 1B and 1C)

The light emitting device according to an embodiment may further include a hole auxiliary layer. The hole auxiliary layer 20 may be disposed between the first electrode 10 and the emission layer 30. The hole auxiliary layer 20 may include a hole injection layer, a hole transport layer, and/or an electron blocking layer. The hole auxiliary layer 20 may be a single component layer or a multilayer structure in which adjacent layers include different components.

The hole auxiliary layer 20 has a HOMO energy level that can be matched with the HOMO energy level of the light emitting layer 30 to enhance mobility of holes transferred from the hole auxiliary layer 20 to the light emitting layer 30. In an embodiment, the hole auxiliary layer 20 may include a hole injection layer close to the first electrode 10 and a hole transport layer close to the emission layer 30.

A material included in the hole auxiliary layer 20 (e.g., a hole transport layer, a hole injection layer, or an electron blocking layer) is not particularly limited. In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

The electron auxiliary layer 40 may be disposed between the light emitting layer 30 and the second electrode 50. The electron auxiliary layer 40 may include, for example, an electron injection layer, an electron transport layer, and/or a hole blocking layer. The electron auxiliary layer may include, for example, an electron injection layer (EIL) that facilitates injection of electrons, an electron transport layer (ETL) that facilitates transport of electrons, a hole blocking layer (HBL) that blocks the movement of holes, or combinations thereof.

In an embodiment, an electron injection layer may be disposed between the electron transport layer and the second electrode. For example, the hole blocking layer may be disposed between the light emitting layer and the electron transport (injection) layer but is not limited thereto. The thickness of each layer may be appropriately selected. For example, the thickness of each layer may be greater than or equal to about 1 nm and less than or equal to about 500 nm but is not limited thereto. The electron injection layer may be an organic layer formed by vapor deposition. The electron transport layer may include inorganic oxide nanoparticles or may be an organic layer formed by vapor deposition.

The electron auxiliary layer 40 may include an electron transport layer. The electron transport layer may include a plurality of nanoparticles. The plurality of nanoparticles may include a metal oxide including zinc. The metal oxide may include zinc oxide, zinc magnesium oxide, or a combination thereof. The metal oxide may include Zn₁₋ₓMₓO, wherein M is Mg, Ca, Zr, W, Li, Ti, Y, Al, or a combination thereof and 0≤x≤0.5. In an embodiment, the M may be magnesium (Mg). In an embodiment, x may be greater than or equal to about 0.01 and less than or equal to about 0.3, for example, less than or equal to about 0.25, less than or equal to about 0.2, or less than or equal to about 0.15. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, each thickness of the electron auxiliary layer 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, respectively, but is not limited thereto.

A device according to an embodiment may have a normal structure. In an embodiment, in the device, the first electrode 10 disposed on the transparent substrate 100 may include a metal oxide-based transparent electrode (e.g., an ITO electrode), and the second electrode 50 facing the first electrode may include a conductive metal (e.g., having a relatively low work function, Mg, Al, etc.). The hole auxiliary layer 20 (e.g., a hole injection layer such as PEDOT:PSS (poly(3,4-ethylenedioxythiophene): polystyrene sulfonate) and/or p-type metal oxide and/or a hole transport layer such as TFB (poly(9,9-dioctyl-fluorene-co-N-(4)-butylphenyl)-diphenylamine)) and/or PVK poly(N-vinylcarbazole)) may be provided between the first (transparent) electrode 10 and the light emitting layer 30. The hole injection layer may be disposed close to the transparent electrode and the hole transport layer may be disposed close to the light emitting layer. An electron auxiliary layer 40 such as an electron injection/transport layer may be disposed between the light emitting layer 30 and the second electrode 50. (See FIG. 1B)

A device according to another embodiment may have an inverted structure. As used herein, the second electrode 50 disposed on the transparent substrate 100 may include a metal oxide-based transparent electrode (e.g., ITO), and the first electrode 10 facing the second electrode may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the second (transparent) electrode 50 and the light emitting layer 30. MoO₃ or other p-type metal oxide may be disposed as a hole auxiliary layer 20 (e.g., a hole transport layer including TFB and/or PVK and/or a hole injection layer including MoO₃ or other p-type metal oxide) between the metal first electrode 10 and the light emitting layer 30. (See FIG. 1C)

The aforementioned device may be manufactured by an appropriate method. For example, the electroluminescent device may be manufactured by optionally forming a hole auxiliary layer (e.g., by deposition or coating) on a substrate on which an electrode is formed, forming a light emitting layer including nanoparticles (e.g., a pattern of the aforementioned nanoparticles), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited.

In an embodiment, the display device may include a first pixel and a second pixel configured to emit light of a color different from that of the first pixel. An electroluminescent device according to an embodiment may be disposed in the first pixel, the second pixel, or a combination thereof, respectively.

In an embodiment, a photoluminescent device or a display device (for example, display panel) may include a light source (or a light emitting panel) and a light conversion element (or a color conversion panel) that includes a light emitting layer, and the light emitting layer includes a film or patterned film of a semiconductor nanoparticle-polymer composite.

The light emitting layer may be disposed on a (e.g., transparent) substrate. The light source is configured to provide incident light to the light conversion element. The incident light may have an emission peak wavelength in a range of greater than or equal to about 360 nm, greater than or equal to about 400 nm, greater than or equal to about 440 nm, greater than or equal to about 450 nm and less than or equal to about 560 nm, less than or equal to about 500 nm, less than or equal to about 480 nm, less than or equal to about 470 nm, or less than or equal to about 460 nm.

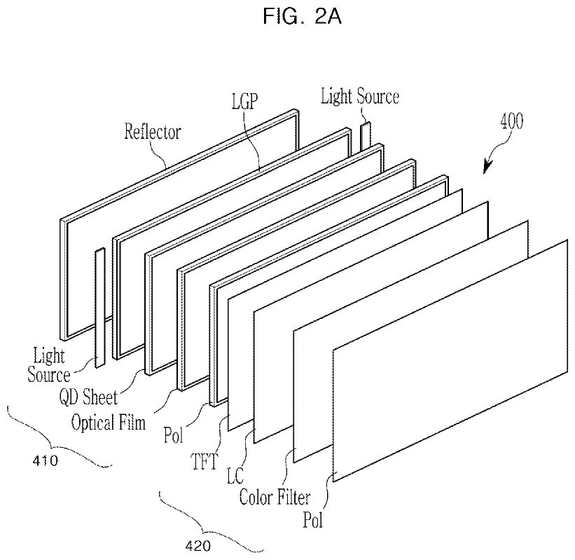

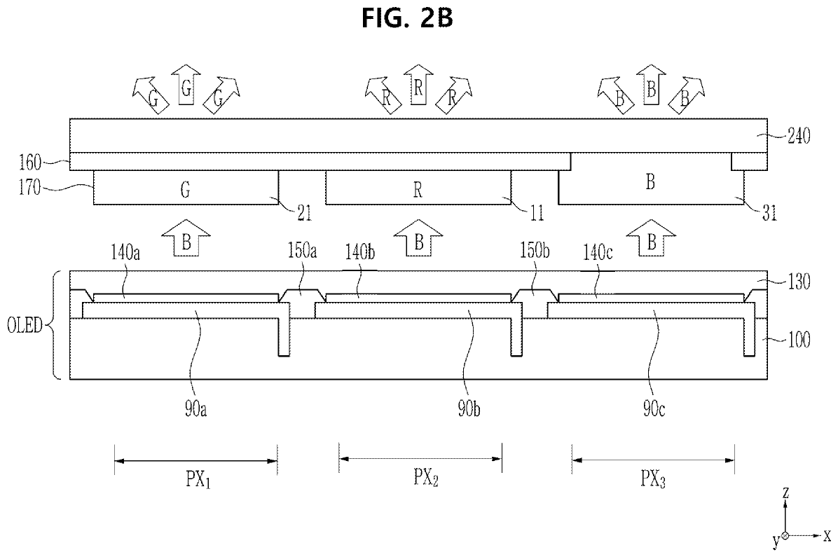

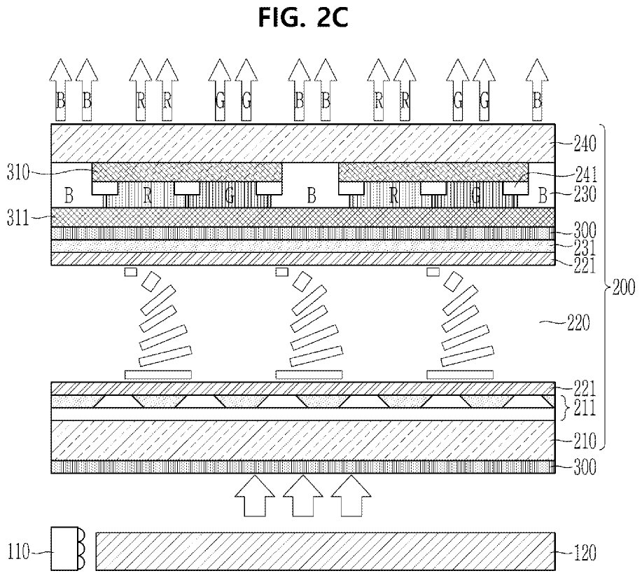

In an embodiment, the light conversion element may include a sheet of the quantum dot-polymer composite. The display device may further include a liquid crystal panel and the sheet of the quantum dot-polymer composite may be disposed between the light source and the liquid crystal panel. FIG. 2A shows an exploded view of a non-limiting display device. Referring to FIG. 2A, the display device may have a structure wherein a reflector, a light guide panel (LGP) and a blue LED light source (blue-LED), the quantum dot-polymer composite sheet (QD sheet), various optical films such as a prism, double brightness enhance film (DBEF), and the like are stacked and a liquid crystal panel (LC) is disposed thereon. The liquid crystal panel 420 is disposed on the backlight unit 410 and may have a structure including a liquid crystal and a color filter between two polarizers Pol. The quantum dot-polymer composite sheet (QD sheet) may include quantum dots that emit red light and quantum dots that emit green light by absorbing light from a light source. Blue light provided from the light source may be converted into white light by being combined with red light and green light emitted from the quantum dots while passing through the quantum dot-polymer composite sheet. The white light may be separated into blue light, green light, and red light by the color filter in the liquid crystal panel and may be emitted to the outside for each pixel.

In the device of an embodiment, the light emitting layer may include a pattern of the semiconductor nanoparticle-polymer composite. The pattern may include at least one repeating section to emit light of a predetermined wavelength. The pattern of the nanocrystal particle-polymer composite may include a first section emitting first light and/or a second section emitting second light. The pattern of the nanocrystal particle-polymer composite may be produced by a photolithography method or an inkjet method as described later.

The light source may be an element emitting excitation light. The excitation light may include blue light and, optionally, green light. The light source may include an LED. The light source may include an organic LED (OLED). The light source may include a micro LED. An optical element that blocks (e.g., reflects or absorbs) blue light (and optionally green light), for example a blue light (and optionally green light) blocking layer or a first optical filter as described later may be disposed on the front surface (light emitting surface) of the first section and the second section. When the light source includes a blue light emitting organic light emitting diode and a green light emitting organic light emitting diode, a green light removing filter may be further disposed on the third section through which the blue light passes.

FIG. 2B is a schematic cross-sectional view of a device (or a display panel) having three (sub) pixels (PX₁, PX₂, PX₃) according to an embodiment. Referring to FIG. 2B, the light source (or light emitting panel) may include an organic light emitting diode emitting blue light (and optionally green light). The organic light emitting diode may include two or more pixel electrodes 90a, 90b, 90c formed on a substrate 100, a pixel defining layer 150a, 150b formed between adjacent pixel electrodes, 90a, 90b, 90c, an organic light emitting layer 140a, 140b, 140c formed on each pixel electrode 90a, 90b, 90c, and a common electrode layer 130 formed on the organic light emitting layer 140a, 140b, 140c. A thin film transistor (TFT) and a substrate may be disposed under the organic light emitting diode (OLED). The pixel area of the OLED may be disposed to correspond to first, second, and third sections to be described later. Although the color conversion panel and the light emitting panel are shown in a separate form in FIG. 2B, the color conversion panel may be stacked directly on the light emitting panel.

A laminated structure including the semiconductor nanoparticle composite pattern 170 (e.g., a first region 11 or R including red light emitting nanocrystal particle, a second region 21 or G including green light emitting nanocrystal particle, and a third region 31 or B including or not including a nanocrystal particle, e.g., a blue light emitting nanocrystal particle) and substrate 240 may be disposed on the light source. The blue light emitted from the light source enters the first region and second region and may emit a red light and a green light, respectively. The blue light emitted from the light source may pass through the third region. An element (a first optical filter 160 or excitation light blocking layer) configured to block the excitation light may be disposed between the semiconductor nanoparticle composite layers R and G and the substrate, if desired. In an embodiment, the excitation light includes a blue light and a green light, and a green light blocking filter (not shown) may be added to the third region. The first optical filter or the excitation light blocking layer will be described in more detail herein.

Non-limiting examples of the display device (e.g., a liquid crystal display device) according to an embodiment are illustrated with reference to the drawing. FIG. 2C is a schematic cross-sectional view showing a liquid crystal display according to an embodiment. Referring to FIG. 2C, the display device of an embodiment includes a liquid crystal panel 200, a polarizing plate 300 disposed under the liquid crystal panel 200, and a backlight unit (BLU) disposed under the polarizing plate 300.

The liquid crystal panel 200 may include a lower substrate 210, a stacked structure, and a liquid crystal layer 220 disposed between the stacked structure and the lower substrate. The stacked structure includes a transparent substrate 240 and a photoluminescent layer 230 including a pattern of a semiconductor nanoparticle-polymer composite.

The lower substrate 210 that is also referred to as an array substrate may be a transparent insulating material substrate. The substrate is the same as described above. A wire plate 211 is provided on an upper surface of the lower substrate 210. The wire plate 211 may include a plurality of gate wires (not shown) and data wires (not shown) that define a pixel area, a thin film transistor disposed adjacent to a crossing region of gate wires and data wires, and a pixel electrode for each pixel area, but is not limited thereto. Details of such a wire plate are known and are not particularly limited.

The liquid crystal layer 220 may be disposed on the wire plate 211. The liquid crystal layer 220 may include an alignment layer 221 on and under the liquid crystal layer 220 to initially align the liquid crystal material included therein. Details (e.g., a liquid crystal material, an alignment layer material, a method of forming liquid crystal layer, a thickness of liquid crystal layer, or the like) of the liquid crystal material and the alignment layer are known and are not particularly limited.

A lower polarizing plate 300 is provided under the lower substrate. Materials and structures of the polarizing plate 300 are known and are not particularly limited. A backlight unit (e.g., emitting blue light) may be disposed under the polarizing plate 300. An upper optical element or an upper polarizing plate 300 may be provided between the liquid crystal layer 220 and the transparent substrate 240, but is not limited thereto. For example, the upper polarizing plate may be disposed between the liquid crystal layer 220 and the photoluminescent layer 230. The polarizing plate may be any polarizer that used in a liquid crystal display device. The polarizing plate may be TAC (triacetyl cellulose) having a thickness of less than or equal to about 200 μm, but is not limited thereto. In another embodiment, the upper optical element may be a coating that controls a refractive index without a polarization function.

The backlight unit includes a light source 110. The light source may emit blue light or white light. The light source may include a blue LED, a white LED, a white OLED, or a combination thereof, but is not limited thereto.

The backlight unit may further include a light guide panel 120. In an embodiment, the backlight unit may be an edge-type lighting. For example, the backlight unit may include a reflector (not shown), a light guide panel (not shown) provided on the reflector and providing a planar light source with the liquid crystal panel 200, and/or at least one optical sheet (not shown) on the light guide panel, for example, a diffusion plate, a prism sheet, and the like, but is not limited thereto. The backlight unit may not include a light guide panel. In an embodiment, the backlight unit may be a direct lighting. For example, the backlight unit may have a reflector (not shown), and may have a plurality of fluorescent lamps disposed on the reflector at regular intervals, or may have an LED operating substrate on which a plurality of light emitting diodes may be disposed, a diffusion plate thereon, and optionally at least one optical sheet. Details (e.g., each component of a light emitting diode, a fluorescent lamp, light guide panel, various optical sheets, and a reflector) of such a backlight unit are known and are not particularly limited.

A black matrix 241 is provided under the transparent substrate 240 and the black matrix 241 has openings and hides a gate line, a data line, and a thin film transistor of the wire plate on the lower substrate. For example, the black matrix 241 may have a lattice shape. The photoluminescent layer 230 is provided in the openings of the black matrix 241 and has a nanoparticle-polymer composite pattern including a first section (R) configured to emit first light (e.g., red light), a second section (G) configured to emit second light (e.g., green light), and a third section (B) configured to emit/transmit, for example blue light. If needed, the photoluminescent layer may further include at least one fourth section. The fourth section may include nanocrystal particle that emit different color from light emitted from the first to third sections (e.g., cyan, magenta, and yellow light).

In the photoluminescent layer 230, sections forming a pattern may be repeated corresponding to pixel areas formed on the lower substrate. A transparent common electrode 231 may be provided on the photoluminescent layer 230.

The third section (B) configured to emit/transmit blue light may be a transparent color filter that does not change an emission spectrum of the light source. In this case, blue light emitted from the backlight unit may enter in a polarized state and may be emitted through the polarizing plate and the liquid crystal layer as it is. If needed, the third section may include nanocrystal particle emitting blue light.

As described above, if desired, the display device or the light emitting device according to an embodiment may further include an excitation light blocking layer or a first optical filter layer (hereinafter, referred to as a first optical filter layer, 310). The first optical filter layer may be disposed between the bottom surfaces of the first section (R) and the second section (G) and the substrate (e.g., the upper substrate 240) or on the upper surface of the substrate. The first optical filter layer may be a sheet having an opening in a portion corresponding to a pixel area (third section) displaying blue, and may be formed in portions corresponding to the first and second sections. That is, the first optical filter layer may be integrally formed at portions other than the portion overlapping the third section as shown in FIGS. 2A and 2B, but the present disclosure is not limited thereto. Two or more first optical filter layers may be spaced apart from each other at portions overlapping the first and second sections, and optionally, the third section. If the light source includes a green light emitting element, a green light blocking layer may be disposed on the third section.

The first optical filter layer may, for example, block light of some wavelength regions of the visible light region and transmit light of the remaining wavelength region, and for example, may block blue light (or green light) and transmit light other than blue light (or green light). The first optical filter layer may transmit, for example, green light, red light, and/or yellow light that is a mixture thereof. The first optical filter layer may transmit blue light and block green light and may be disposed on the blue light emitting pixel.

The first optical filter layer may substantially block excitation light and transmit light in a desired wavelength region. The transmittance of the first optical filter layer for light in a desired wavelength region may be greater than or equal to about 70%, greater than or equal to about 80%, greater than or equal to about 90%, or even 100%.

A first optical filter layer selectively transmitting red light may be disposed on the portion overlapped with the section emitting red light and the first optical filter layer selectively transmitting green light may be disposed on the portion overlapped with the section emitting green light, respectively. The first optical filter layer may include at least one of a first section that blocks (e.g., absorbs) blue light and red light and selectively transmits light in a predetermined range (e.g., greater than or equal to about 500 nm, greater than or equal to about 510 nm, or greater than or equal to about 515 nm and less than or equal to about 550 nm, less than or equal to about 545 nm, less than or equal to about 540 nm, less than or equal to about 535 nm, less than or equal to about 530 nm, less than or equal to about 525 nm, or less than or equal to about 520 nm), and a second region that blocks (e.g., absorbs) blue light and green light, and selectively transmits light in a predetermined range (e.g., greater than or equal to about 600 nm, greater than or equal to about 610 nm, or greater than or equal to about 615 nm and less than or equal to about 650 nm, less than or equal to about 645 nm, less than or equal to about 640 nm, less than or equal to about 635 nm, less than or equal to about 630 nm, less than or equal to about 625 nm, or less than or equal to about 620 nm). When the light source emits blue and green mixed light, the first optical filter may further include a third region that selectively transmits blue light and blocks green light.

The display device may further include a second optical filter layer (e.g., a red/green or yellow light recycle layer) 311 disposed between the photoluminescent layer and the liquid crystal layer (e.g., the photoluminescent layer and the upper polarizing plate, e.g., polarizer), transmitting at least a portion of third light (excitation light), and reflecting a, e.g., at least one, part of the first light, part of the second light, or part of each of the first light and second light. The first light may be red light, the second light may be green light, and the third light may be blue light. For example, the second optical filter layer may transmit only the third light (B) in a blue light wavelength region having a wavelength region of less than or equal to about 500 nm and light in a wavelength region of greater than about 500 nm, which is green light (G), yellow light, red light (R), or the like, may be not passed through the second optical filter layer and reflected. The reflected green light and red light may pass through the first and second sections and to be emitted to the outside of the display device.

The first region may be disposed at a portion overlapped with the green light emitting section. The second region may be disposed at a portion overlapped with the red light emitting section. The third region may be disposed at a portion overlapped with the blue light emitting section.

The first region, the second region, and optionally the third region may be optically isolated. The first optical filter layer may contribute to improving color purity of a display device.

The display device or the electronic device may include a television, VR/AR, a mobile terminal, a monitor, a notebook computer, a television, an electric sign board, a camera, or an electronic component.

Hereinafter, the exemplary embodiments are illustrated in further detail with reference to examples. However, embodiments of the present disclosure are not limited to the examples.

### EXAMPLES

### Analysis Methods

### [1] UV-Vis Absorption Spectroscopy

A UV-Vis absorption spectroscopic analysis was performed using Agilent Cary5000 spectrophotometer and a UV-Visible absorption spectrum is obtained.

### [2] Photoluminescence Analysis

A photoluminescence (PL) spectrum of the semiconductor nanoparticle was obtained using a Hitachi F-7000 spectrophotometer at an excitation wavelength of 400 nm.

### [3] ICP Analysis

Inductively coupled plasma atomic emission spectroscopy (ICP-AES) was conducted using a Shimadzu ICPS-8100.

### [4] TEM Analysis

A transmission electron microscopic analysis of the semiconductor nanoparticle was performed by using an UT F30 Tecnai electron microscope.

### Example 1

Sulfur was dissolved in trioctylphosphine to provide a 1 M S-TOP (hereinafter, “sulfur precursor”). Indium chloride was dissolved in ethanol to provide a 0.2 M indium precursor containing solution (hereinafter, “indium precursor”).

Gallium acetylacetonate and dodecanethiol were added to a flask containing oleylamine (OAm) and octadecene (ODE), and the contents placed under vacuum. Nitrogen was then introduced into the flask and silver acetate (i.e., a silver precursor), and the indium precursor were added to the flask to provide a reaction solution. The reaction solution was heated to a temperature of about 260° C. and a reaction was allowed to proceed for 45 minutes. After decreasing the temperature of the flask to 180° C., trioctylphosphine (TOP) was added followed by the addition of hexane and ethanol to the flask (reaction product mixture) to facilitate the formation of a precipitate. The precipitate was separated via centrifugation and the resulting semiconductor nanocrystal dispersed in toluene.

A mole ratio of the silver, the gallium, the indium, and the sulfur added to the reaction flask was 4.3:7.7:1:15.8, respectively.
[2] Gallium chloride was dissolved in toluene to prepare a 4.5 M gallium precursor containing solution (hereinafter, “gallium precursor”).

Dimethylthiourea (DMTU), oleyl amine, and dodecanethiol were added to a reaction flask and vacuum-treated at 120° C. for 10 minutes. Nitrogen was introduced into the flask and at the temperature of the flask is raised to 240° C. (addition temperature). The semiconductor nanocrystal of Example 1 [1] and the gallium precursor were added to the flask. The reaction flask was then heated to 280° C. (a second temperature) for about 15 minutes (a second reaction time). The reaction solution was cooled to 180° C. and trioctylphosphine was added to the flask. The reaction solution was then cooled to room temperature. Hexane and ethanol were added to facilitate precipitation of the semiconductor nanoparticle, which were recovered via centrifugation and re-dispersed in toluene.

A mole ratio of the gallium precursor to the sulfur precursor as used was 1.4:1.

An ICP-AES analysis was conducted for the semiconductor nanoparticle thus obtained, and the results are shown in Table 1. A photoluminescence spectroscopy analysis was conducted with the semiconductor nanoparticle thus obtained, and the results are shown in Table 2.

### Example 2

[1] The semiconductor nanocrystal was prepared in the same manner as Example 1 except that in the reaction solution a mole ratio of the silver, the gallium, the indium, and the sulfur (Ag:Ga:In:S) was 2.0:6.6:1:13.6, respectively, and the TOP was not added after the reaction.

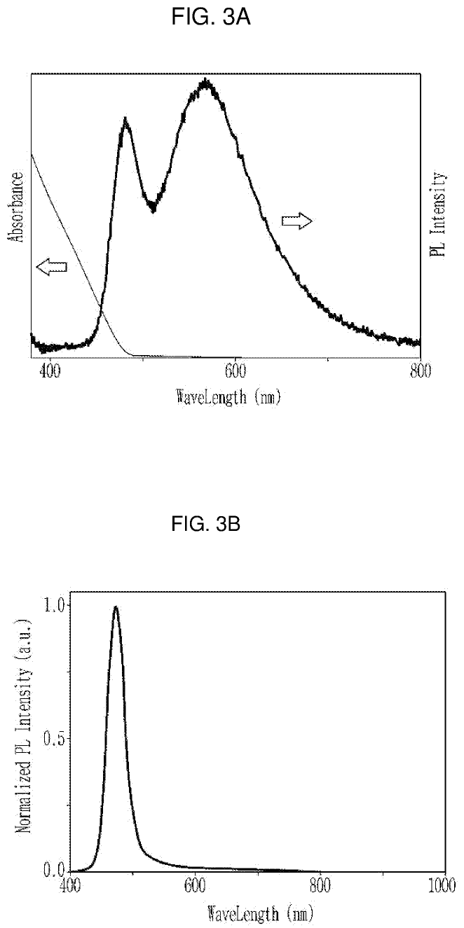

A UV-Vis absorption spectroscopy and a photoluminescence analysis were conducted for the semiconductor nanocrystals thus obtained, and the results are shown in FIG. 3A. From the results of FIG. 3A, the semiconductor nanocrystals exhibit a first peak (band edge emission peak) at about 460 nm and a second peak (trap emission peak) at about 550 nm.
[2] The semiconductor nanoparticle was prepared in the same manner as Example 1, except that the semiconductor nanocrystal of Example 2[1] was used. An ICP-AES analysis was conducted for the semiconductor nanoparticle thus obtained, and the result is shown in Table 1. A photoluminescence spectroscopy analysis was conducted with the semiconductor nanoparticle thus obtained, and the result is shown in Table 2 and FIG. 3B.

### Example 3

[1] The semiconductor nanocrystal was prepared in the same manner as Example 1 except that in the reaction solution a mole ratio of the silver, the gallium, the indium, and the sulfur (Ag:Ga:In:S) was 1.4:4.6:1:9.5, respectively.

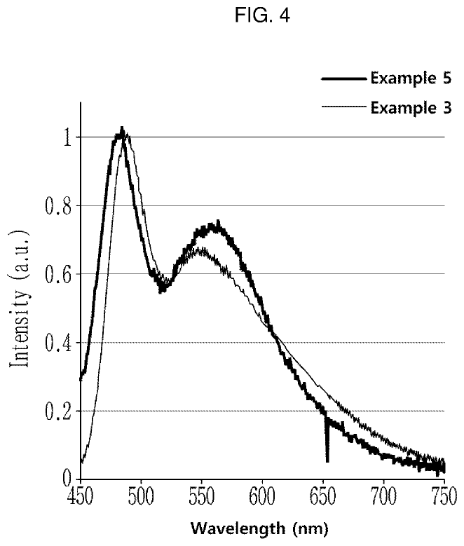

A UV-Vis absorption spectroscopy and a photoluminescence analysis were conducted for the semiconductor nanocrystal thus obtained, and the results are shown in FIG. 4. From the results of FIG. 4, the semiconductor nanocrystals exhibit a first peak (band edge emission peak) at about 489 nm and a second peak (trap emission peak) at about 550 nm.
[2] The semiconductor nanoparticle was prepared in the same manner as Example 1 except that the semiconductor nanocrystal obtained in Example 3[1] was used. An ICP-AES analysis was conducted with the semiconductor nanoparticle thus obtained, and the results are shown in Table 1. A photoluminescence spectroscopy analysis was conducted with the semiconductor nanoparticle of Example 3[2], and the results are shown in Table 2.

### Example 4

[1] The semiconductor nanocrystal was prepared in the same manner as Example 1 except that in the reaction solution a mole ratio of the silver, the gallium, the indium, and the sulfur (Ag:Ga:In:S) was 2.0:6.6:1:13.6, respectively.
[2] The semiconductor nanoparticle was prepared in the same manner as Example 1 except that the semiconductor nanocrystal obtained in Example 4[1] was used. An ICP-AES analysis was conducted with the obtained semiconductor nanoparticle thus obtained, and the results are shown in Table 1. A photoluminescence spectroscopy analysis was conducted with the semiconductor nanoparticle thus obtained, and the results are shown in Table 2.

### Example 5

[1] The semiconductor nanocrystal was prepared in the same manner as Example 1 except that in the reaction solution a mole ratio of the silver, the gallium, the indium, and the sulfur (Ag:Ga:In:S) was 2.0:6.6:1:13.6, respectively, the nitrogen was introduced to the flask, the flask was heated to 120° C. and cooled to room temperature, and then the silver precursor, the sulfur precursor, and the indium precursor were to the cooled flask.

A UV-Vis absorption spectroscopy and a photoluminescence analysis were conducted for the obtained semiconductor nanocrystal, and the results are shown in FIG. 4. From the results of FIG. 4, the semiconductor nanocrystal exhibits a first peak (band edge emission peak) at about 482 nm and a second peak (trap emission peak) at about 570 nm.
[2] The semiconductor nanoparticle was prepared in the same manner as Example 1 except that the semiconductor nanocrystal of Example 5[1] was used. An ICP-AES analysis was conducted with respect to the semiconductor nanoparticle thus obtained, and the results are shown in Table 1. A photoluminescence spectroscopy analysis was conducted with the semiconductor nanoparticle thus obtained, and the results are shown in Table 2.

### Comparative Example 1 (CE1)

[1] The semiconductor nanocrystal was prepared in the same manner as Example 1 except that in the reaction solution a mole ratio of the silver, the gallium, the indium, and the sulfur (Ag:Ga:In:S) was 1:3.1:1:6.3, respectively.
[2] The semiconductor nanoparticle was prepared in the same manner as Example 1 except that the semiconductor nanocrystal obtained in CE2[1] was used. An ICP-AES analysis was conducted with semiconductor nanoparticle thus obtained, and the results are shown in Table 1. A photoluminescence spectroscopy analysis was conducted with the semiconductor nanoparticle thus obtained, and the results are shown in Table 2.

TABLE 1

| | Ag:S | In:S | Ga:S | Ga:(In + Ga) | (In + Ga):Ag | Ag:(AIG) ¹ | S:(AIG) ¹ |
|---|---|---|---|---|---|---|---|
| Example 1 | 0.3155 | 0.0458 | 0.6230 | 0.9315 | 2.120 | 0.3205 | 1.016 |
| Example 2 | 0.2585 | 0.0487 | 0.8312 | 0.9446 | 3.403 | 0.2271 | 0.878 |
| Example 3 | 0.3188 | 0.0731 | 0.6917 | 0.9044 | 2.399 | 0.2942 | 0.923 |
| Example 4 | 0.2579 | 0.0574 | 0.7820 | 0.9316 | 3.255 | 0.2350 | 0.911 |
| Example 5 | 0.1918 | 0.0417 | 1.1655 | 0.9654 | 6.293 | 0.1371 | 0.715 |
| Comp. | 0.3450 | 0.1560 | 0.8286 | 0.8415 | 2.854 | 0.2595 | 0.752 |
| Example 1 | | | | | | | |

¹ AIG = sum total moles ratio of silver, indium, and gallium.

TABLE 2

| | | | Quantum | |
|---|---|---|---|---|
| | Peak emission | FWHM | yield | Trap emission |
| | wavelength (nm) | (nm) | (QY, %) | percentage (%) |
| Example 1 | 461 | 30 | 46 | 6.1 |
| Example 2 | 473 | 32 | 73 | 4.9 |
| Example 3 | 480 | 34 | 49 | 9.4 |
| Example 4 | 472 | 31 | 67 | 6.2 |
| Example 5 | 470 | 30 | 60 | 4.6 |
| Comp. | 502 | 44 | 45 | 34.5 |
| Example 1 | | | | |

FWHM: Full width at half maximum
Trap emission percentage: a percentage of the trap emission value [(A2/A1) × 100(%)]
A1 is an intensity at the peak emission wavelength, and
A2 is a maximum intensity in a tail wavelength range of the peak emission wavelength + greater than or equal to 60 nm

The results of Table 2 confirmed that the semiconductor nanoparticles of Examples 1 to 5 emit blue light and exhibit an improved luminous property in comparison with the semiconductor nanoparticle of Comparative Example 1.

While this disclosure has been described in connection with what is presently considered to be practical embodiments, it is to be understood that the present subject matter is not limited to the disclosed exemplary embodiments. On the contrary, it is intended to cover various modifications and equivalent arrangements included within the spirit and scope of the appended claims.

What is claimed is:

1. A semiconductor nanoparticle comprising:
silver, indium, gallium, and sulfur, wherein the semiconductor nanoparticle is configured to emit blue light, and the blue light has a peak emission wavelength of greater than or equal to about 400 nanometers and less than 490 nanometers,
wherein the semiconductor nanoparticle is configured to have a quantum yield of greater than or equal to about 40% and a full width at half maximum of less than about 70 nanometers.

2. The semiconductor nanoparticle of claim 1, wherein the peak emission wavelength is greater than or equal to about 410 nanometers and less than or equal to about 480 nanometers.

3. The semiconductor nanoparticle of claim 1, wherein the semiconductor nanoparticle is configured to have a full width at half maximum of less than about 55 nm, a quantum yield of greater than or equal to about 45%, or both.

4. The semiconductor nanoparticle of claim 1, wherein in a photoluminescence spectrum of the semiconductor nanoparticle, a trap emission value defined by Equation 1 is less than about 0.3:
trap emission value=A2/A1 Equation 1
wherein, in Equation 1,
A1 is an intensity at a peak emission wavelength, and
A2 is a maximum intensity in a tail wavelength range of the peak emission wavelength+greater than or equal to 60 nm.

5. The semiconductor nanoparticle of claim 1, wherein a mole ratio of gallium to a sum of indium and gallium, [Ga:(In+Ga)] is greater than or equal to about 0.85:1 and less than or equal to about 0.995:1.

6. The semiconductor nanoparticle of claim 1, wherein
a mole ratio of indium to sulfur [In:S] is greater than or equal to about 0.01:1, and less than or equal to about 0.08:1;
a mole ratio of silver to sulfur [Ag:S] is greater than or equal to about 0.1 and less than or equal to about 0.34:1; or
a mole ratio of gallium to sulfur (Ga:S) is greater than or equal to about 0.77:1 and less than or equal to about 2.5:1, or
any combination thereof is satisfied.

7. The semiconductor nanoparticle of claim 1, wherein
a mole ratio of a sum of indium and gallium to silver [(In+Ga):Ag] is greater than or equal to about 1.9:1 and less than or equal to about 7:1; or
a mole ratio of silver to a sum of silver, indium, and gallium [Ag:(Ag+In+Ga)] is greater than or equal to about 0.09:1 and less than about 0.38:1, or
a combination thereof is satisfied.

8. The semiconductor nanoparticle of claim 1, wherein
a mole ratio of sulfur to a sum of silver, indium, and gallium [S:(Ag+In+Ga)] is greater than or equal to about 0.7:1 and less than or equal to about 1.35:1.

9. The semiconductor nanoparticle of claim 1, wherein at least four of the following mole ratios is satisfied:
a mole ratio of gallium to a sum of indium and gallium, [Ga:(In+Ga)] is greater than or equal to about 0.85:1 and less than or equal to about 0.995:1.
a mole ratio of indium to sulfur [In:S] is greater than or equal to about 0.01:1, and less than or equal to about 0.08:1;
a mole ratio of silver to sulfur [Ag:S] is greater than or equal to about 0.1 and less than or equal to about 0.34:1;
a mole ratio of gallium to sulfur (Ga:S) is greater than or equal to about 0.77:1 and less than or equal to about 2.5:1,
a mole ratio of a sum of indium and gallium to silver [(In+Ga):Ag] is greater than or equal to about 1.9:1 and less than or equal to about 7:1; or
a mole ratio of silver to a sum of silver, indium, and gallium [Ag:(Ag+In+Ga)] is greater than or equal to about 0.09:1 and less than about 0.38:1.

10. The semiconductor nanoparticle of claim 1,
wherein the semiconductor nanoparticle does not comprise lithium.

11. The semiconductor nanoparticle of claim 1,
wherein in the semiconductor nanoparticle, an indium amount in a portion adjacent to a surface of the semiconductor nanoparticle is less than an indium amount in a central portion of the semiconductor nanoparticle.

12. A method for producing the semiconductor nanoparticle of claim 1, the method comprising:
heating a first reaction solution comprising a first metal precursor and a first sulfur precursor to a first reaction temperature to prepare a semiconductor nanocrystal; and
reacting a second metal precursor and a second sulfur precursor in an organic solvent in the presence of the semiconductor nanocrystal to prepare the semiconductor nanoparticle, wherein the first metal precursor comprises a first silver compound, a first gallium compound, and a first indium compound, and the second metal precursor includes a second gallium compound and, optionally, a second silver compound, and
wherein in the first reaction solution, a mole ratio of gallium to indium is greater than or equal to about 3.5:1, and the first reaction temperature is greater than or equal to about 240° C.

13. The method of claim 12, wherein
in the first reaction solution, a mole ratio of gallium to indium as determined from the first gallium compound and the first indium compound is greater than or equal to about 4:1 and less than or equal to about 20:1, and
a first reaction temperature is greater than or equal to about 255° C. and less than about 300° C.

14. The method of claim 12, wherein a photoluminescent spectrum of the semiconductor nanocrystal exhibits a first emission peak at a wavelength of less than 500 nm and a second emission peak at a wavelength of greater than 500 nm.

15. The method of claim 12, wherein the reacting of the second metal precursor with the second sulfur precursor comprises:
preparing a reaction medium containing the second sulfur precursor and an organic ligand in the organic solvent;
heating the reaction medium to an addition temperature;
adding the semiconductor nanocrystal and the second metal precursor to the reaction medium to obtain a reaction mixture;
heating the reaction mixture to a second reaction temperature, wherein the addition temperature is greater than or equal to about 120° C. and less than or equal to about 280° ° C., the second reaction temperature is greater than or equal to about 180° C. and less than or equal to about 380° C.

16. An ink composition comprising a liquid vehicle, and a semiconductor nanoparticle of claim 1.

17. A composite comprising:
a matrix; and
the semiconductor nanoparticle of claim 1,
wherein the semiconductor nanoparticle is dispersed in the matrix.

18. A device comprising:
a color conversion layer comprising a color conversion region, and optionally, partition walls defining the color conversion region,
wherein the color conversion region comprises a first region corresponding to a first pixel, and
wherein the first region comprises the composite of claim 17.

19. An electroluminescent device, comprising:
a first electrode and a second electrode spaced apart from each other; and
a light emitting layer between the first electrode and the second electrode;
wherein the light emitting layer comprises the semiconductor nanoparticle of claim 1.

20. A display device comprising the semiconductor nanoparticle of claim 1.
